(19) United States
(12) Patent Application Publication
(10) Pub. No.: US 2024/0405047 A1
(43) Pub. Date: Dec. 5, 2024

(54) OPTICAL BLOCKING REGIONS FOR PIXEL SENSORS

(71) Applicant: Taiwan Semiconductor Manufacturing Company, Ltd., Hsinchu (TW)

(72) Inventors: Feng-Chien HSIEH, Pingtung City (TW); Yun-Wei CHENG, Taipei City (TW); Wei-Li HU, Tainan City (TW); Kuo-Cheng LEE, Tainan City (TW); Cheng-Ming WU, Tainan City (TW)

(21) Appl. No.: 18/325,699

(22) Filed: May 30, 2023

(51) Int. Cl. H01L 27/146

(52) U.S. Cl. CPC H01L 27/14629; H01L 27/1463; H01L 27/14636; H01L 27/14645; H01L 27/14685

(57) ABSTRACT

An optical blocking region formed with patterned metal reduces light reflection toward pixel sensors in a pixel sensor array. The optical blocking region may be formed of a metal nanoscale grid in order to reflect more light away from the pixel sensors. The optical blocking region may include a dielectric layer, supporting the patterned metal, with high absorption structures or shallow deep trench isolation structures in order to increase absorption and thus reduce light reflection toward the pixel sensors.

### BACKGROUND

Complementary metal oxide semiconductor (CMOS) image sensor (CIS) devices utilize light-sensitive CMOS circuitry to convert light energy into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

Light received by pixel sensors of a CIS device is often based on the three primary colors: red, green, and blue (R, G, B). Pixel sensors that sense light for each color can be defined through the use of a color filter that allows the light wavelength for a particular color to pass into a photodiode. Some pixel sensors may include a near infrared (NIR) pass filter, which blocks visible light and passes NIR light through to the photodiode.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example image sensor device described herein.

FIGS. 3A-3D are diagrams of example semiconductor devices described herein.

FIGS. 4A-4N are diagrams of an example implementation described herein.

FIGS. 5A-5I are diagrams of an example implementation described herein.

FIGS. 6A-6I are diagrams of an example implementation described herein.

FIGS. 7A-7L are diagrams of an example implementation described herein.

FIGS. 8A-8L are diagrams of an example implementation described herein.

FIG. 9 is a diagram of example components of one or more devices of FIG. 1 described herein.

FIG. 10 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An image sensor device (e.g., a complementary metal oxide semiconductor (CMOS) image sensor (CIS) device) may include a black level correction (BLC) region adjacent to and/or surrounding a pixel sensor array of the image sensor device. The BLC region includes one or more layers of light-blocking material that prevents light from entering a sensing region under the one or more layers. The sensing region is “dark” in that the one or more layers prevent incident light from entering the sensing region, which enables the sensing region to generate a dark current measurement for black level correction (or black level calibration) for the pixel sensor array. Dark current is an electrical current that occurs in the image sensor device as a result of an energy source other than incident light. Dark current may result from, for example, heat generated by the image sensor device and/or by one or more other devices near the image sensor device. Dark current can cause noise and other defects in images and/or video captured by the image sensor device. For example, dark current can artificially increase the photocurrent generated by pixel sensors in the pixel sensor array, which can result in elevated black levels and/or can cause some of the pixels in an image or a video to register as a white pixel or a hot pixel.

The light-blocking material used in the BLC region may be metallic and reflective. While high reflectivity may result in increased light-blocking performance, the reflectivity of the light-blocking material also causes light to be reflected toward the pixel sensors in the pixel sensor array. The light reflected toward the pixel sensors in the pixel sensor array can cause flares or hot spots (e.g., areas of increased brightness) in images and/or videos generated by the image sensor device, and/or can otherwise reduce the image quality of the images and/or videos generated by the image sensor device.

Some implementations described herein provide techniques and apparatuses for an optical blocking region with patterned metal in order to reduce light reflection toward pixel sensors in a pixel sensor array. In some implementations, the optical blocking region may be formed of a metal nanoscale grid in order to reflect more light away from the pixel sensors. In some implementations, the optical blocking region may include a dielectric layer, supporting the metal, with high absorption (HA) structures or shallow deep trench isolation (DTI) structures in order to increase absorption and thus reduce light reflection toward the pixel sensors. The optical blocking region may reduce the likelihood of occurrence of flares or hot spots in images and/or videos generated by the image sensor device, which may increase the image quality of the images and/or videos generated by the image sensor device.

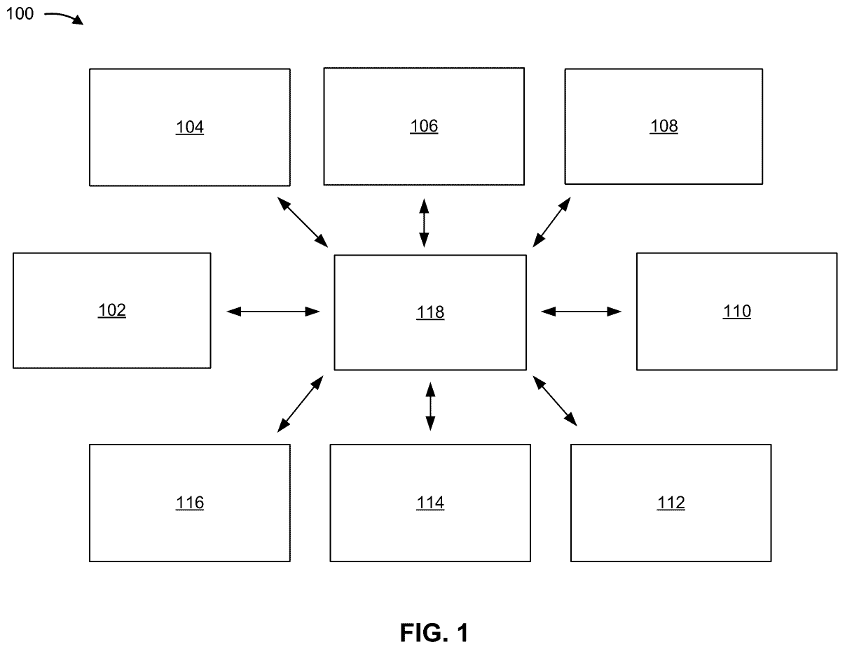

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, a photoresist removal tool 114, an annealing tool 116, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The photoresist removal tool 114 is a semiconductor processing tool that is capable of removing remaining portions of a photoresist layer from a substrate after the etch tool 108 removes portions of the substrate. For example, the photoresist removal tool 114 may use a chemical stripper and/or another technique to remove a photoresist layer from a substrate.

The annealing tool 116 is a semiconductor processing tool that includes a semiconductor processing chamber and one or more devices capable of heating a semiconductor substrate or semiconductor device. For example, the annealing tool 116 may include a rapid thermal annealing (RTA) tool or another type of annealing tool that is capable of heating a semiconductor substrate to cause a reaction between two or more materials or gasses, to cause a material to decompose. As another example, the annealing tool 116 may be configured to heat (e.g., raise or elevate the temperature of) a structure or a layer (or portions thereof) to re-flow the structure or the layer, or to crystallize the structure or the layer, to remove defects such as voids or seams. As another example, the annealing tool 116 may be configured to heat (e.g., raise or elevate the temperature of) a layer (or portions thereof) to enable bonding of two or more semiconductor devices.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may forming, in a substrate, an isolation structure around at least one photodiode; pattern a portion of the substrate, corresponding to an optical blocking region, to form a recessed pattern; form a dielectric layer over the isolation structure and over the portion of the substrate corresponding to the optical blocking region, such that the dielectric layer conforms to the recessed pattern; and/or form a metal layer over the dielectric layer, such that the metal layer conforms to the recessed pattern in the optical blocking region, among other examples.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

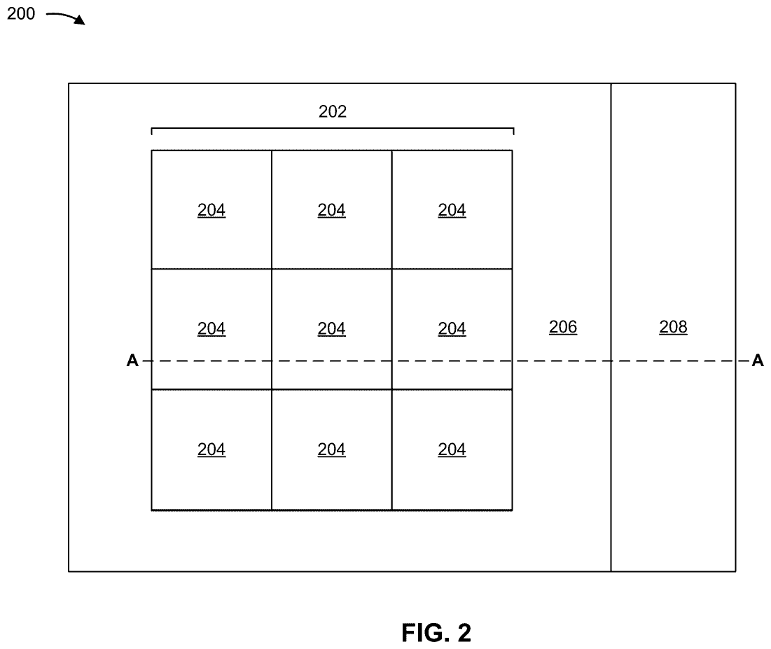

FIG. 2 is a diagram of a top-down view of an example image sensor device 200 described herein. The image sensor device 200 may include a CMOS image sensor, a back side illuminated (BSI) CMOS image sensor, and/or another type of image sensor. The image sensor device 200 may be configured to be deployed in various implementations, such as digital cameras, video recorders, night-vision cameras, automotive sensors and cameras, and/or other types of light-sensing implementations.

The image sensor device 200 may include a pixel sensor array 202. As shown in FIG. 2, the pixel sensor array 202 may include a plurality of pixel sensors 204. As further shown in FIG. 2, the pixel sensors 204 may be arranged in a grid. In some implementations, the pixel sensors 204 are square-shaped (as shown in the example in FIG. 2). In some implementations, the pixel sensors 204 include other shapes such as circle shapes, octagon shapes, diamond shapes, and/or other shapes.

The pixel sensors 204 may be configured to sense and/or accumulate incident light (e.g., light directed toward the pixel sensor array 202). For example, a pixel sensor 204 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness).

The pixel sensor array 202 may be electrically connected to a back-end-of-line (BEOL) metallization stack (not shown) of the image sensor. The BEOL metallization stack may electrically connect the pixel sensor array 202 to control circuitry that may be used to measure the accumulation of incident light in the pixel sensors 204 and convert the measurements to an electrical signal.

As further shown in FIG. 2, the image sensor device 200 may include an optical blocking region 206 adjacent to and/or surrounding a pixel sensor array 202. The optical blocking region 206 includes one or more layers of light-blocking material that prevents light from entering a sensing region under the one or more layers. The sensing region is “dark” in that the one or more layers prevent incident light from entering the sensing region. This enables the sensing region to generate a dark current measurement for black level correction (or black level calibration) for the pixel sensor array 202. The optical blocking region 206 may be located approximately 25 microns to approximately 200 microns from an edge of image sensor device 200. However, other values for the range are within the scope of the present disclosure.

As further shown in FIG. 2, the image sensor device 200 may include an electrical pad region 208 (which may also be referred to as an e-pad region) adjacent to the optical blocking region 206. The electrical pad region 208 may include one or more metallization layers (e.g., conductive bonding pads, e-pads, metallization layers, vias) through which electrical connections between the image sensor device 200 and outside devices and/or external packaging may be established.

In some implementations, the image sensor device 200 includes one or more other regions, such as a scribe line region that separates one semiconductor die or portion of a semiconductor die that includes the image sensor device 200 from an adjacent semiconductor die or portion of the semiconductor die that includes other image sensor devices and/or other integrated circuits.

As indicated above, FIG. 2 is provided as an example. Other examples may differ from what is described with regard to FIG. 2.

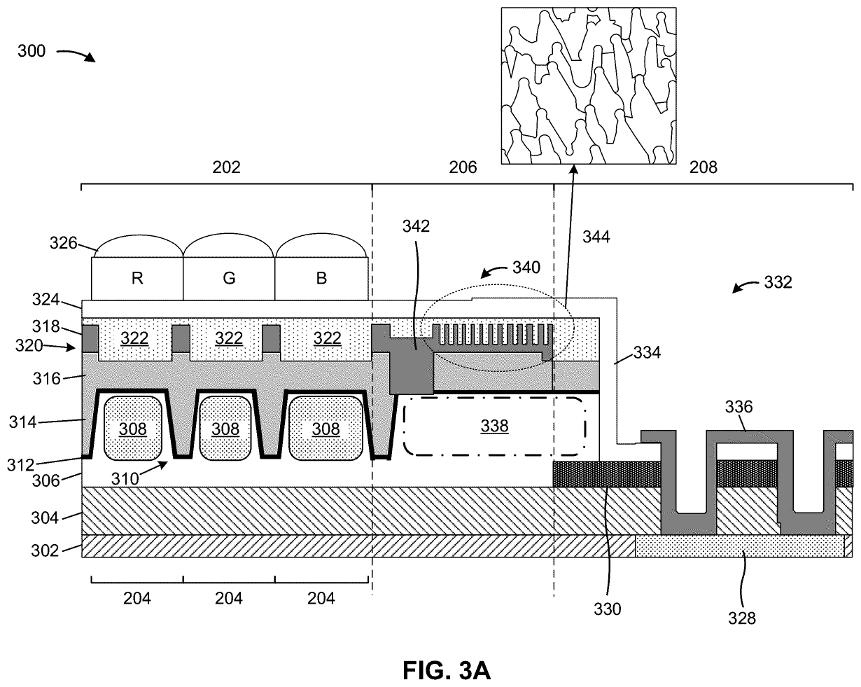

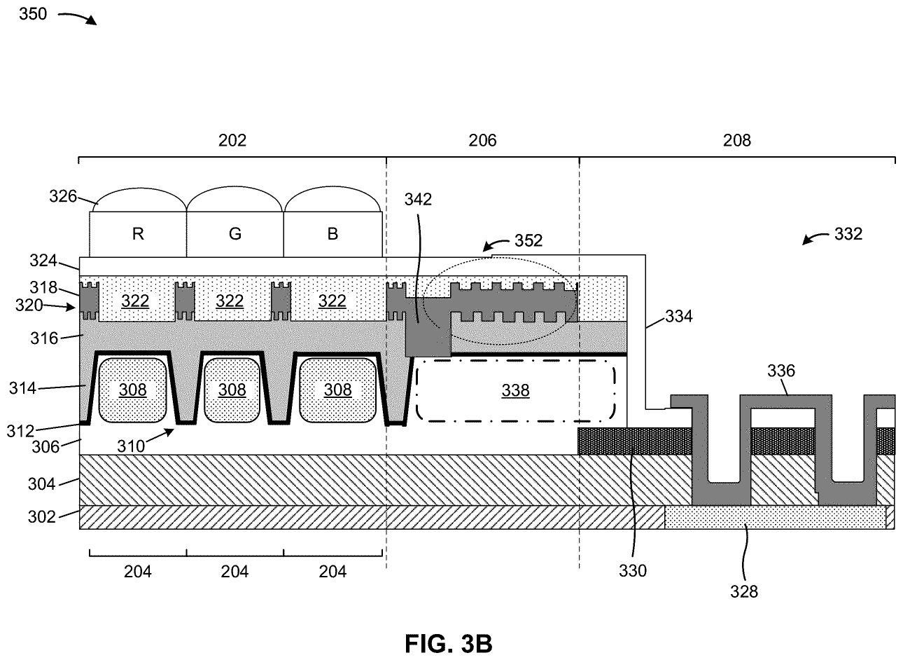

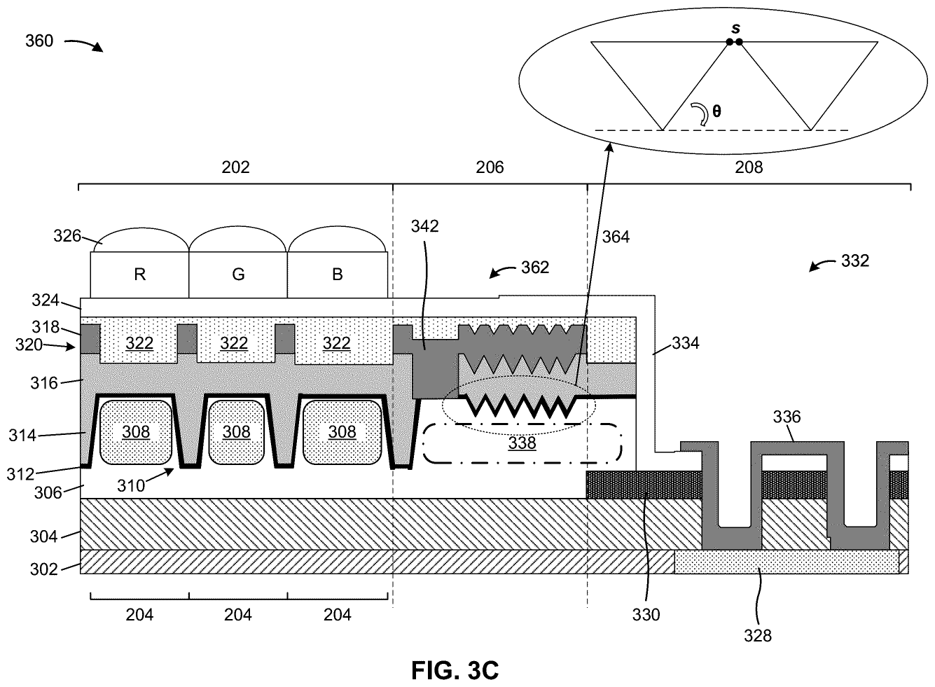

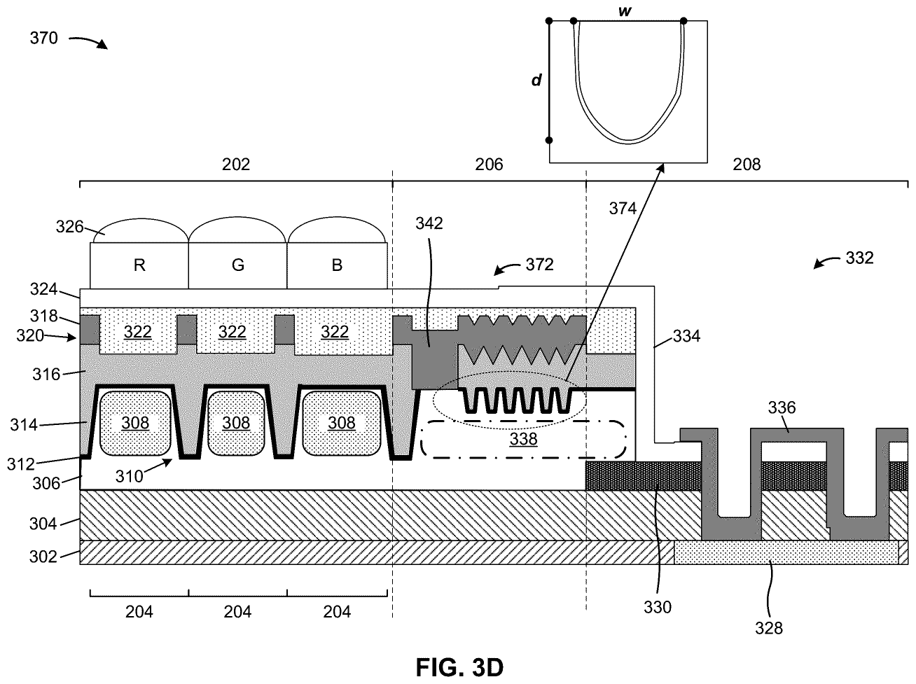

FIGS. 3A-3D are diagrams of example semiconductor devices described herein. The example semiconductor devices may be example image sensor devices, which may be configured as, or included in, the image sensor device 200 of FIG. 2. Each semiconductor device includes an optical blocking region formed of patterned metal in order to increase light reflected away from a pixel sensor array and reduce light reflected toward the pixel sensor array.

FIG. 3A is a diagram of a cross-sectional view of an example image sensor device 300 described herein. The cross-section is shown along the line A-A in FIG. 2. Therefore, FIG. 3A illustrates a subset of cross-sectional structures and/or layers of the image sensor device 200 included in the pixel sensor array 202, the optical blocking region 206, and the electrical pad region 208.

As shown in FIG. 3A, the example image sensor device 300 may include various layers and/or structures. In some implementations, the example image sensor device 300 be mounted and/or fabricated on a carrier substrate (not shown) during one or more semiconductor processing operations to form the example image sensor device 300. The example image sensor device 300 may include an inter-metal dielectric (IMD) layer 302, an interlayer dielectric (ILD) layer 304 over and/or on the IMD layer 302, and a substrate 306 over and/or on the ILD layer 304. The IMD layer 302 and the ILD layer 304 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. The substrate 306 may be formed of silicon (Si), a material including silicon, a III-V compound semiconductor material such as gallium arsenide (GaAs), a silicon on insulator (SOI), or another type of semiconductor material that is capable of generating a charge from photons of incident light.

Various metallization layers may be formed in and/or in between layers of the IMD layer 302. The metallization layers may include bonding pads, conductive lines, and/or other types of conductive structures that electrically connect the various regions of the image sensor device 200 and/or electrically connect the various regions of the example image sensor device 300 to one or more external devices and/or external packaging. The metallization layers may be referred to as a BEOL metallization stack, and may include a conductive material such as gold (Au), copper (Cu), silver (Ag), cobalt (Co), tungsten (W), titanium (Ti), ruthenium (Ru), a metal alloy, and/or a combination thereof, among other examples. The BEOL metallization stack may electrically connect the pixel sensor array 202, the optical blocking region 206, and/or the electrical pad region 208 to a device die on which integrated processing circuitry is included in implementations in which the example image sensor device 300 includes a plurality of stacked and bonded semiconductor dies.

Photodiodes 308 for the pixel sensors 204 in the pixel sensor array 202 may be included in the substrate 306. A photodiode 308 may include a region of the substrate 306 that is doped with a plurality of types of ions to form a p-n junction or a PIN junction (e.g., a junction between a p-type portion, an intrinsic (or undoped) type portion, and an n-type portion). For example, the substrate 306 may be doped with an n-type dopant to form a first portion (e.g., an n-type portion) of a photodiode 308 and a p-type dopant to form a second portion (e.g., a p-type portion) of the photodiode 308. A photodiode 308 may be configured to absorb photons of incident light. The absorption of photons causes a photodiode 308 to accumulate a charge (referred to as a photocurrent) due to the photoelectric effect. Here, photons bombard the photodiode 308, which causes emission of electrons of the photodiode 308. The emission of electrons causes the formation of electron-hole pairs, where the electrons migrate toward the cathode of the photodiode 308 and the holes migrate toward the anode, which produces the photocurrent.

An isolation structure 310 may be included in the substrate 306. The isolation structure 310 may include trenches that extend from a top surface of the substrate 306 and into the substrate 306 around the photodiodes 308 of the pixel sensors 204. In this way, the photodiodes 308 are surrounded by the trenches of the isolation structure 310. In some implementations, the isolation structure 310 may be a DTI structure, such as a backside DTI (BDTI) structure that is formed as a part of back side processing of the example image sensor device 300.

The trenches of the isolation structure 310 may provide optical isolation between the pixel sensors 204 of the pixel sensor array 202, which may reduce the amount of optical crosstalk between adjacent pixel sensors 204. In particular, the trenches of the isolation structure 310 may absorb, refract, and/or reflect incident light, which may reduce the amount of incident light that travels through a pixel sensor 204 into an adjacent pixel sensor 204 and is absorbed by the adjacent pixel sensor 204.

Surfaces of the isolation structure 310 may be coated with an antireflective coating (ARC) 312 to decrease reflection of incident light away from the photodiodes 308 and to increase transmission of incident light into the substrate 306 and the photodiodes 308. The ARC 312 may include a suitable material for reducing a reflection of incident light projected toward the photodiodes 308, such as a nitrogen-containing material or other examples.

The isolation structure 310 may include a dielectric layer 314 above the substrate 306 and above and/or on the ARC 312. Moreover, the dielectric layer 314 may fill the trenches of the isolation structure 310. The dielectric layer 314 may be combined with an adhesion layer 316 between the substrate 306 and the upper layers of the pixel sensor array 202. An adhesion layer 316 may extend above the isolation structure 310 to promote adhesion between the silicon of the substrate 306 and a metal layer 318 above the substrate 306. In some implementations, the dielectric layer 314 and the adhesion layer 316 may be a singular structure that includes an oxide material such as a silicon oxide (SiOₓ). In some implementations, a silicon nitride (SiNₓ), a silicon carbide (SiCₓ), or a mixture thereof, such as a silicon carbon nitride (SiCN), a silicon oxynitride (SiON), or another dielectric material is used in place of the dielectric layer 314 as the adhesion layer 316.

The metal layer 318 may be located over and/or on the adhesion layer 316. The metal layer 318 may extend laterally across the pixel sensor array 202. A metal grid 320 may be formed in the metal layer 318 in the pixel sensor array 202 to provide optical isolation between pixel sensors 204 in the pixel sensor array 202. The metal grid 320 may include columns or pillars surrounding the pixel sensors 204. The columns or pillars of the metal grid 320 may be located over the trenches of the isolation structure 310. The metal layer 318 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

Color filter regions 322 of the pixel sensors 204 may be included between the metal grid 320. In other words, the color filter regions 322 may be included in place of removed portions of the metal layer 318 above the photodiodes 308. Each color filter region 322 may be configured to filter incident light to allow a particular wavelength of the incident light to pass to a photodiode 308 of an associated pixel sensor 204. For example, a color filter region 322 included in a pixel sensor 204 may filter red light (and thus, the pixel sensor 204 may be a red pixel sensor). As another example, a color filter region 322 included in a pixel sensor 204 may filter green light (and thus, the pixel sensor 204 may be a green pixel sensor). As another example, a color filter region 322 included in a pixel sensor 204 may filter blue light (and thus, the pixel sensor 204 may be a blue pixel sensor).

A blue filter region may permit the component of incident light near a 450 nanometer wavelength to pass through a color filter region 322 and block other wavelengths from passing. A green filter region may permit the component of incident light near a 550 nanometer wavelength to pass through a color filter region 322 and block other wavelengths from passing. A red filter region may permit the component of incident light near a 650 nanometer wavelength to pass through a color filter region 322 and block other wavelengths from passing. A yellow filter region may permit the component of incident light near a 580 nanometer wavelength to pass through a color filter region 322 and block other wavelengths from passing.

In some implementations, the color filter region 322 may be non-discriminating or non-filtering, which may define a white pixel sensor. A non-discriminating or non-filtering color filter region 322 may include a material that permits all wavelengths of light to pass into the associated photodiode 308 (e.g., for purposes of determining overall brightness to increase light sensitivity for the image sensor). In some implementations, a color filter region 322 may be a near infrared (NIR) bandpass color filter region, which may define an NIR pixel sensor. An NIR bandpass color filter region 322 may include a material that permits the portion of incident light in an NIR wavelength range to pass to an associated photodiode 308 while blocking visible light from passing.

One or more passivation layers may be formed above and/or on the metal layer 318. For example, a dielectric layer 324 may be located over and/or on portions of the metal layer 318. In some implementations, the dielectric layer 324 may also be included over the optical blocking region 206 and/or at least a portion of the electrical pad region 208, as shown in FIG. 3A. The dielectric layer 324 may include an oxide material such as a silicon oxide (SiOₓ). Additionally and/or alternatively, a silicon nitride (SiNₓ), a silicon carbide (SiCₓ), or a mixture thereof, such as a silicon carbon nitride (SiCN), a silicon oxynitride (SiON), or another dielectric material is used in place of the dielectric layer 324.

A micro-lens layer 326 may be included over and/or on the color filter regions 322 and over and/or on the metal grid 320. The micro-lens layer 326 may include a respective micro-lens for each of the pixel sensors 204. A micro-lens may be formed to focus incident light toward the photodiode 308 of a pixel sensor 204.

As shown in the electrical pad region 208 of the example image sensor device 300, electrical connections may be formed to a metallization layer 328 in the IMD layer 302. A shallow trench isolation (STI) region 330 may be located above and/or over the metallization layer 328. The STI region 330 may provide electrical isolation in the electrical pad region 208. The STI region 330 may be located below and/or under a recess 332 in the electrical pad region 208. Above, the STI region 330, a dielectric layer 334 may be included in the recess 332 on sidewalls and on the bottom surface of the recess 332. An electrical pad 336 may be located in the electrical pad region 208 above the STI region 330, and/or above and/or on the dielectric layer 334. The electrical pad 336 may extend through the dielectric layer 334, through the STI region 330, and through the ILD layer 304 to the IMD layer 302, and may contact the metallization layer 328 in the IMD layer 302. The electrical pad 336 may include a conductive material, such as such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

As shown in the optical blocking region 206, a sensing region 338 may be included in the substrate 306. The sensing region 338 may include a portion of the substrate 306 under the metal layer 318. The optical blocking region 206 further includes a nanoscale metal grid 340 that functions as a light-blocking region to prevent light from entering the sensing region 338. This enables the sensing region 338 to generate a dark current measurement for black level correction (or black level calibration) for the pixel sensor array 202.

In some implementations, the optical blocking region 206 may include a grounding node 342 connecting (electrically and physically) the nanoscale metal grid 340 to the substrate 306. The grounding node 342 maintains the nanoscale metal grid 340 at an electrical neutral, even as photons collide with the nanoscale metal grid 340. As a result, current does not leak from the nanoscale metal grid 340 to the pixel sensor array 202, which improves performance of the example image sensor device 300.

As further shown by reference number 344, the nanoscale metal grid 340 includes a plurality of metal structures, and each metal structure has a width in a range from approximately 100 nanometers (nm) to approximately 200 nm. Selecting a width of at least 100 nm preserves reflective properties of the metal structures such that light is less likely to pass through the metal structures and into the pixel sensor array 202. Selecting a width of no more than 200 nm increases a density of the metal structures such that light is more likely to be reflected rather than pass through the nanoscale metal grid 340 and into the pixel sensor array 202. The metal grid is therefore “nanoscale” because each metal structure of the metal grid has a dimension (e.g., a width and/or a height) that is smaller than approximately 250 nm.

The nanoscale metal grid 340 reduces the likelihood of light being reflected off of metal in the optical blocking region 206 and toward the pixel sensor array 202. In this way, the nanoscale metal grid 340 reduces a likelihood of occurrence of flares or hot spots in images and/or videos generated by the example image sensor device 300, which increases image quality.

FIG. 3B is a diagram of a cross-sectional view of an example image sensor device 350 described herein. The cross-section is shown along the line A-A in FIG. 2. FIG. 3B is similar to FIG. 3A except that the optical blocking region 206 includes a recessed pattern 352 in metal (e.g., a portion of the metal layer 318 in the optical blocking region 206) that functions as a light-blocking region to prevent light from entering the sensing region 338. This enables the sensing region 338 to generate a dark current measurement for black level correction (or black level calibration) for the pixel sensor array 202.

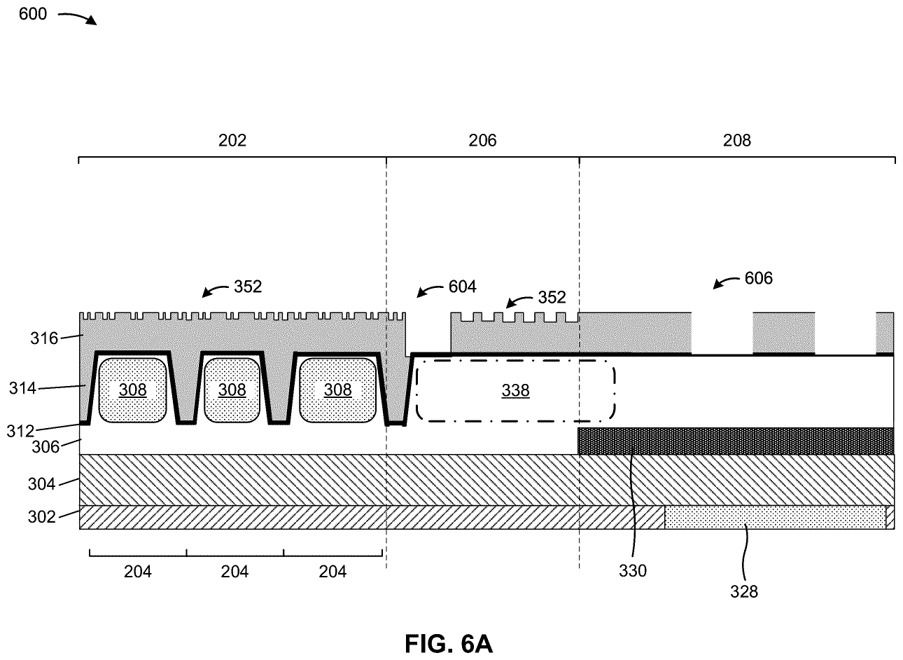

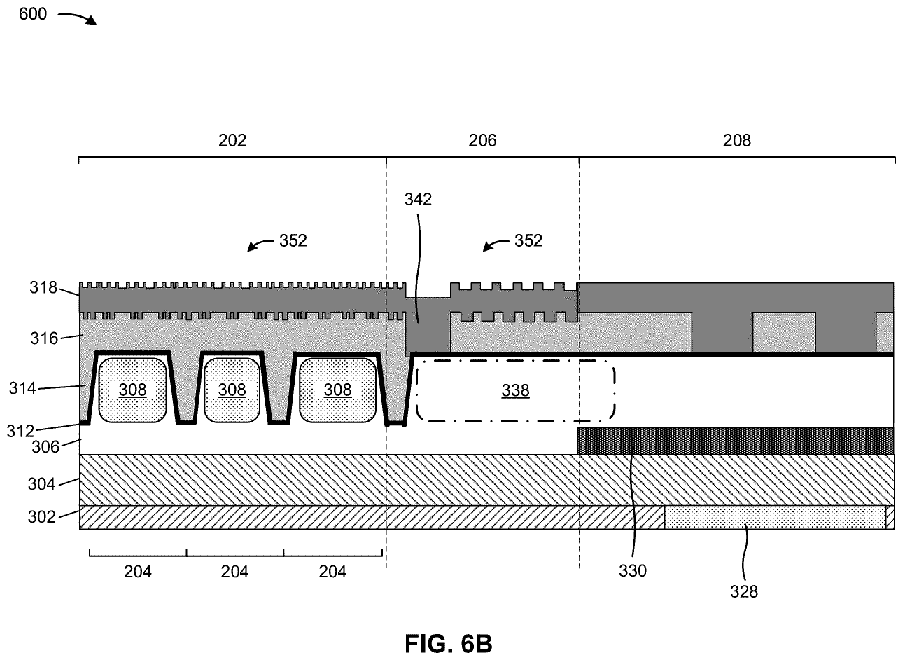

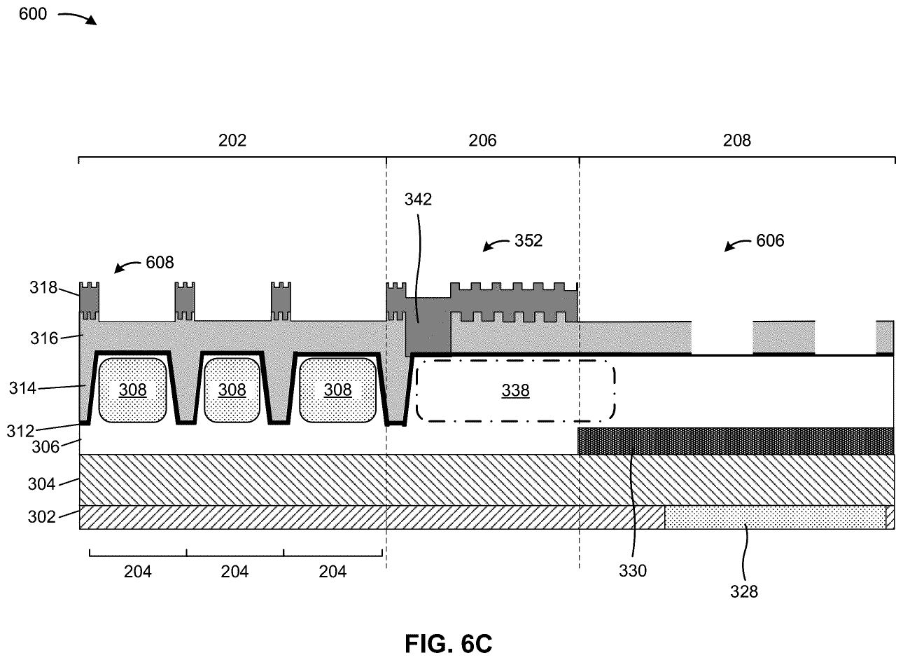

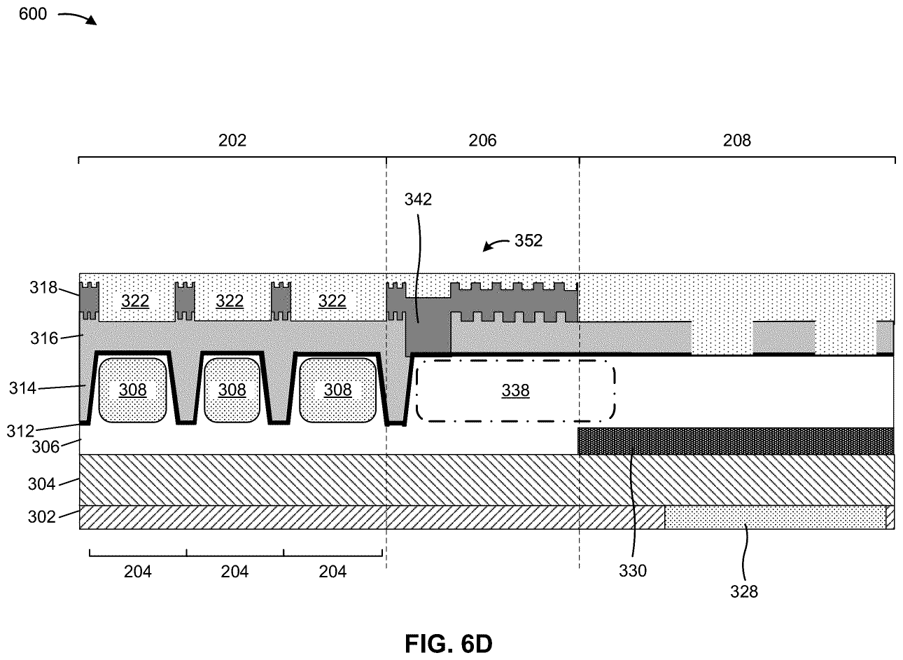

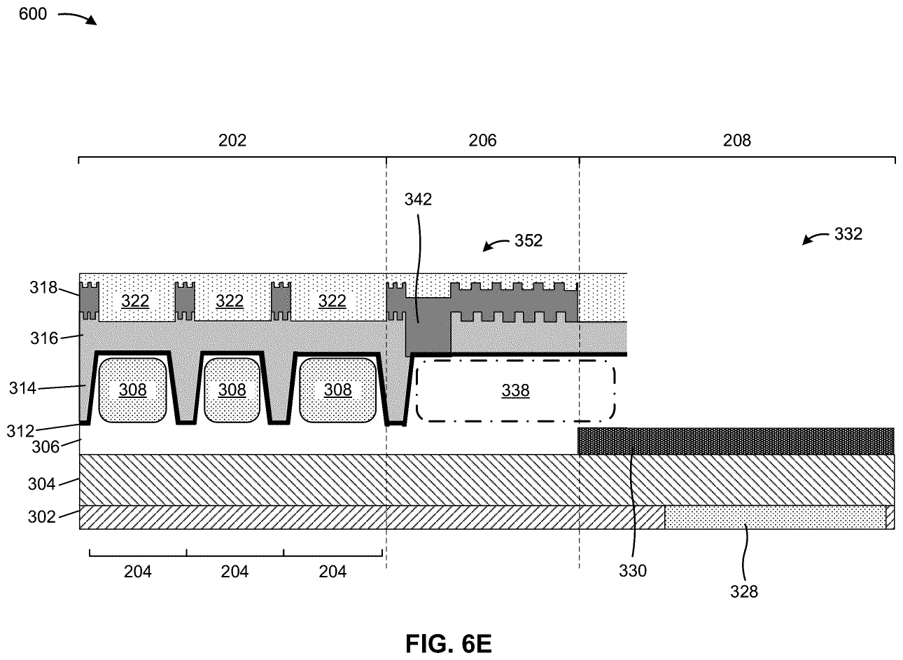

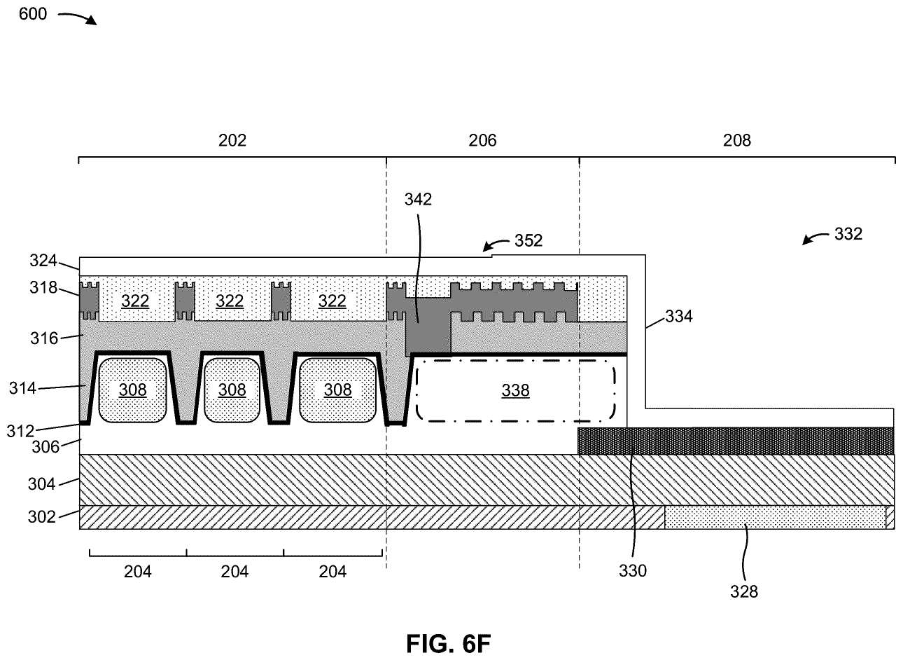

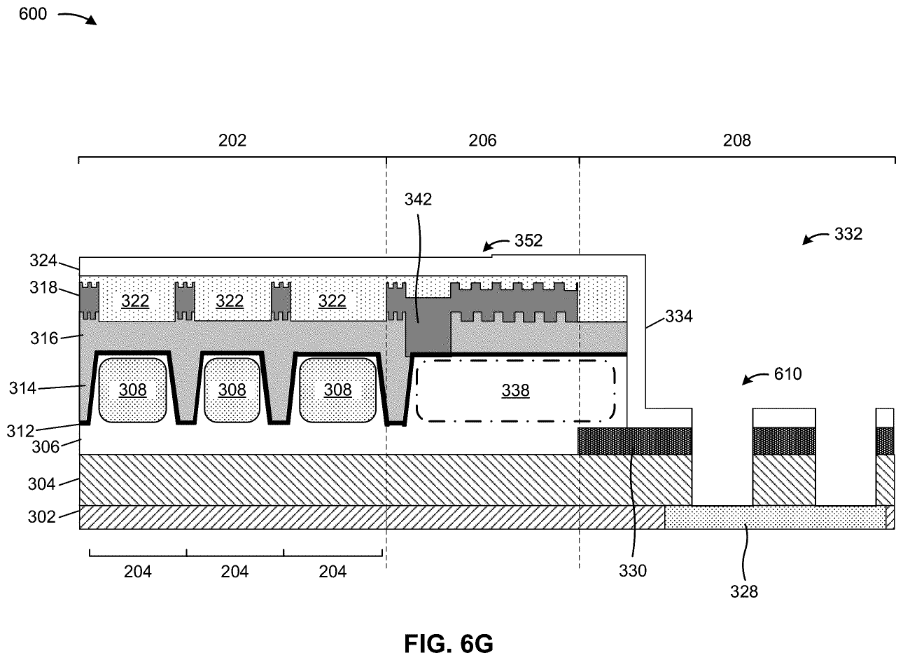

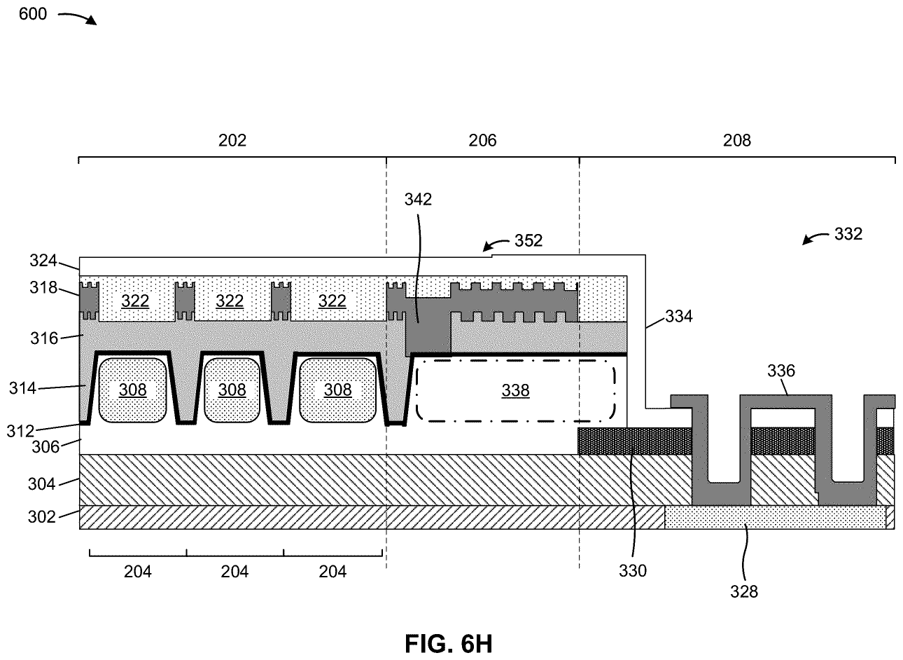

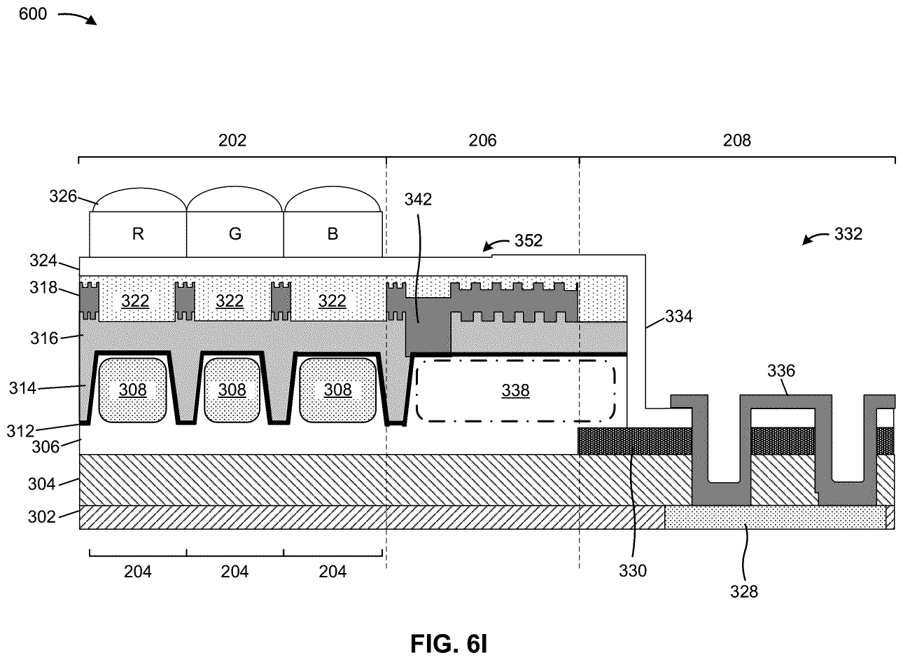

As further shown in FIG. 3B, a portion of the adhesion layer 316 in the optical blocking region 206 conforms to the recessed pattern 352. As a result, and as described in connection with FIG. 6C, a portion of the metal layer 318 in the optical blocking region 206 will follow the recessed pattern 352 during deposition. The metal layer 318 may include a plurality of metal structures that jut above a top surface of the metal layer 318. Each metal structure may be larger than the “nanoscale” structures described above (e.g., having a width and/or a height greater than 250 nm). Because larger metal structures are formed by the recessed pattern 352 in the adhesion layer 316, fewer lithography processes are used as compared with forming smaller metal structures.

In some implementations, as described in connection with FIG. 6A, to simplify patterning of the adhesion layer 316, a portion of the adhesion layer 316 in the pixel sensor array 202 may also conform to the recessed pattern 352. As a result, and as shown in FIG. 3B, a portion of the metal layer 318 in the pixel sensor array 202 will also follow the recessed pattern 352 during deposition.

FIG. 3C is a diagram of a cross-sectional view of an example image sensor device 360 described herein. The cross-section is shown along the line A-A in FIG. 2. FIG. 3C is similar to FIG. 3A except that the optical blocking region 206 includes a recessed pattern 362 in metal (e.g., a portion of the metal layer 318 in the optical blocking region 206) that functions as a light-blocking region to prevent light from entering the sensing region 338. This enables the sensing region 338 to generate a dark current measurement for black level correction (or black level calibration) for the pixel sensor array 202.

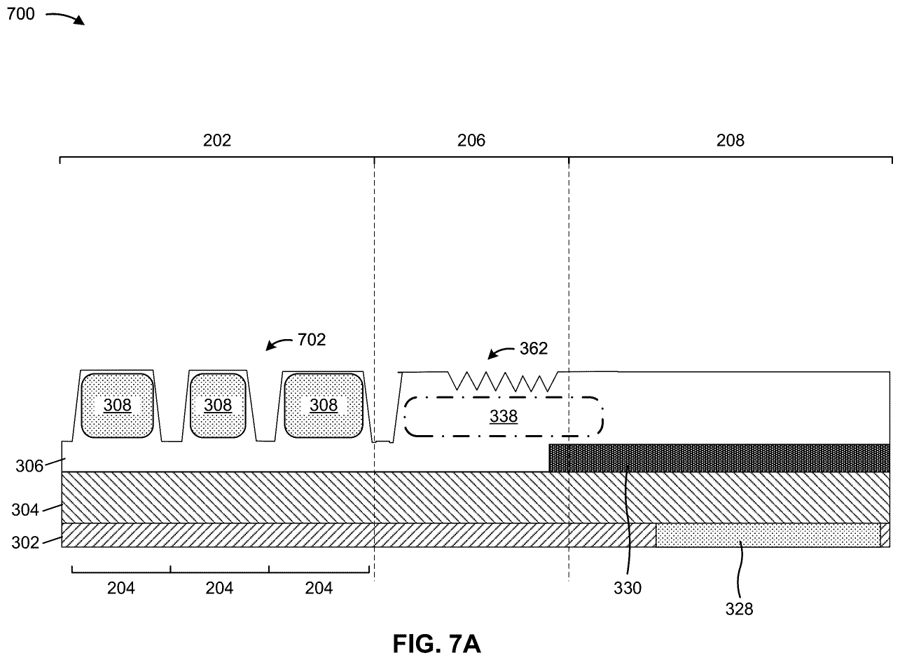

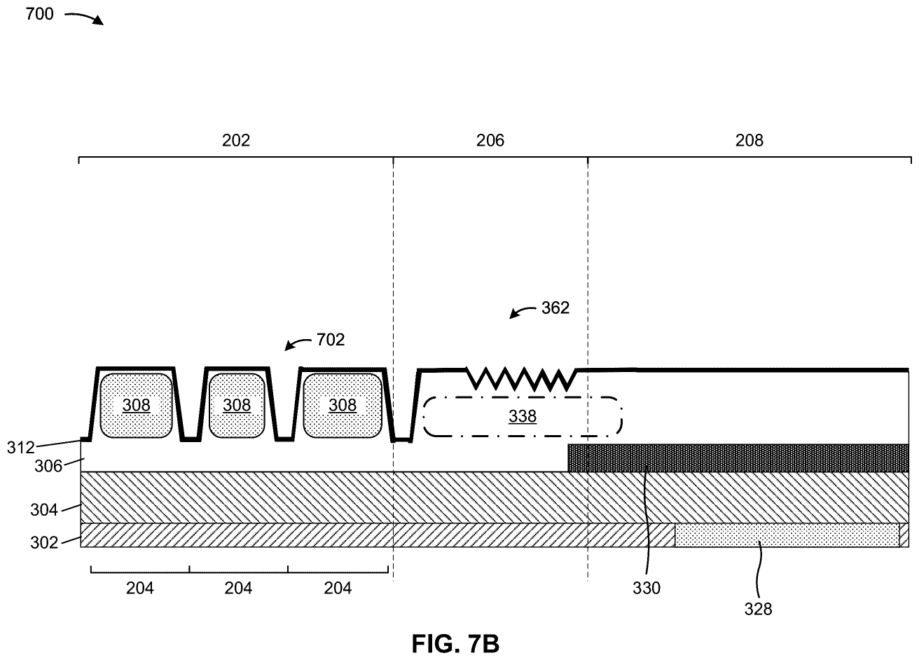

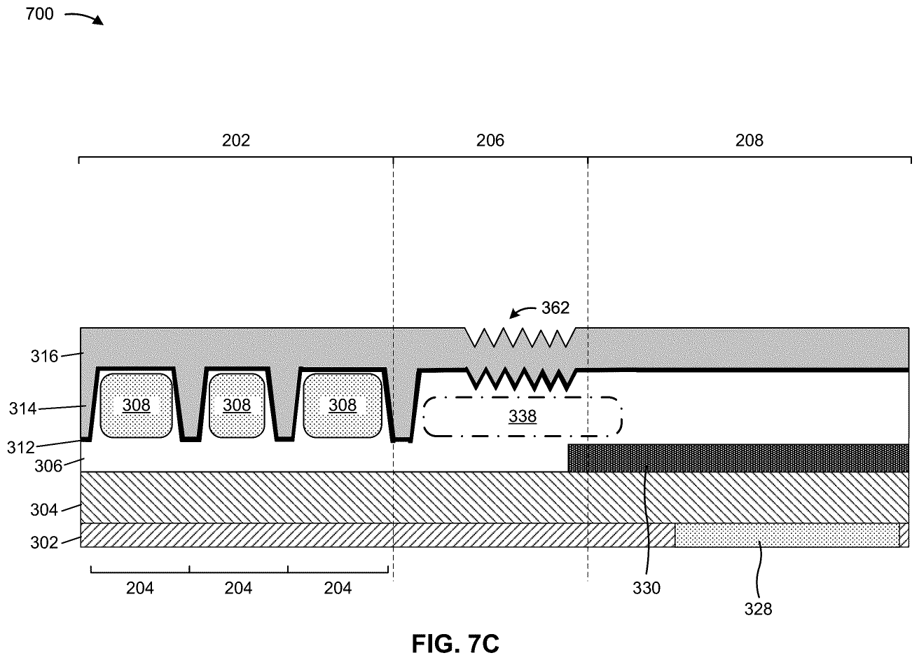

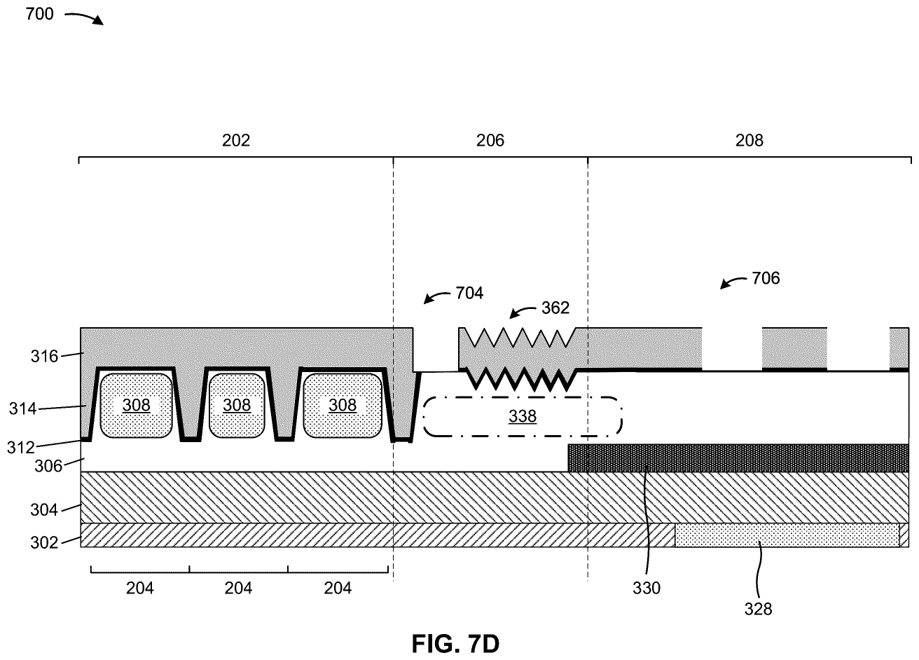

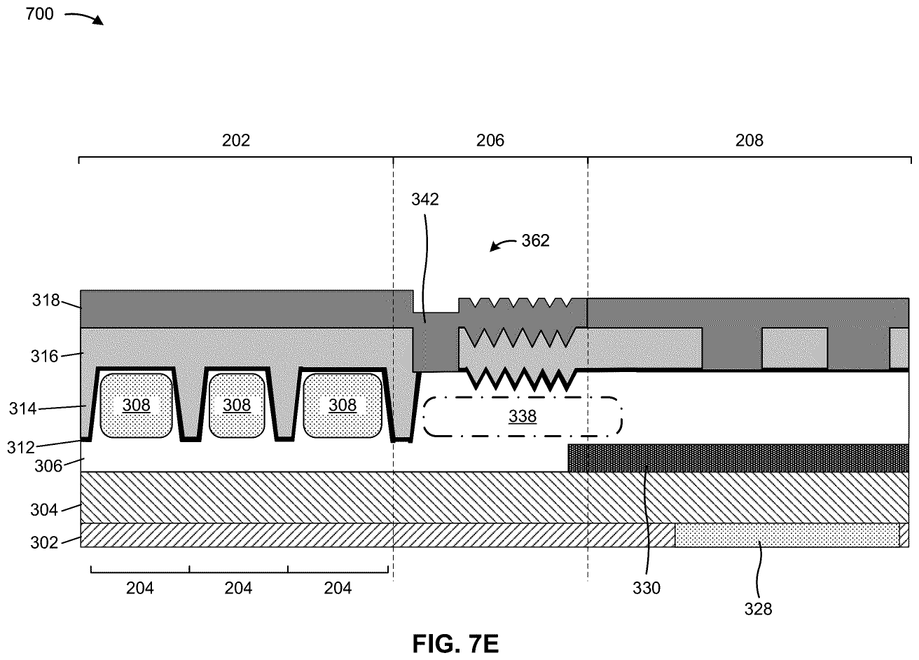

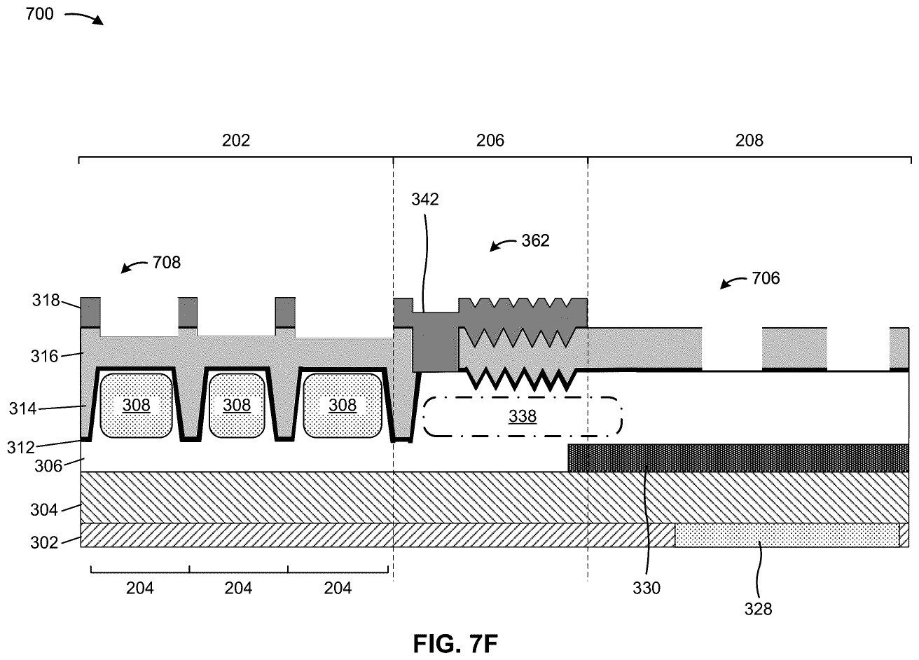

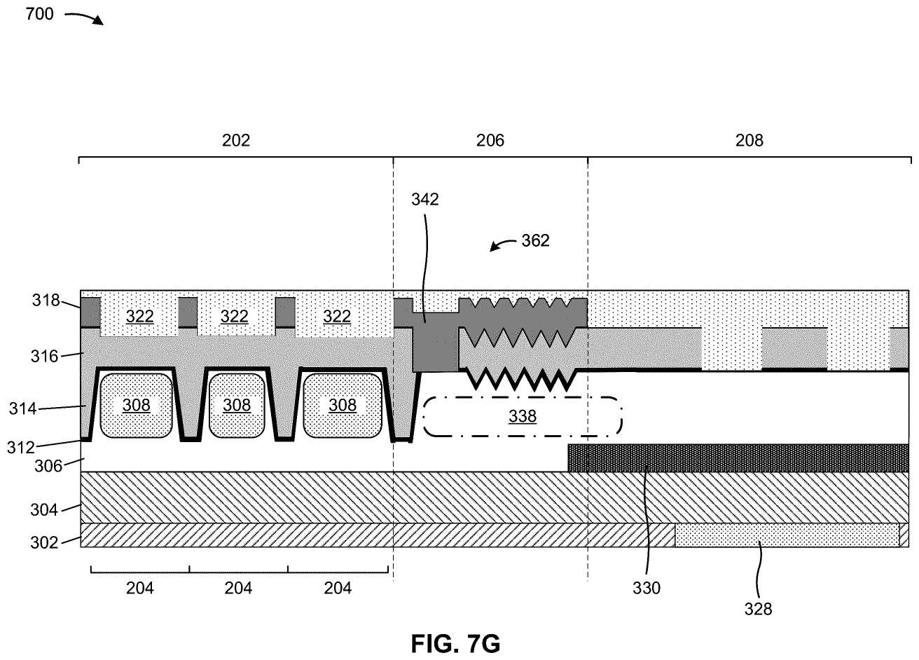

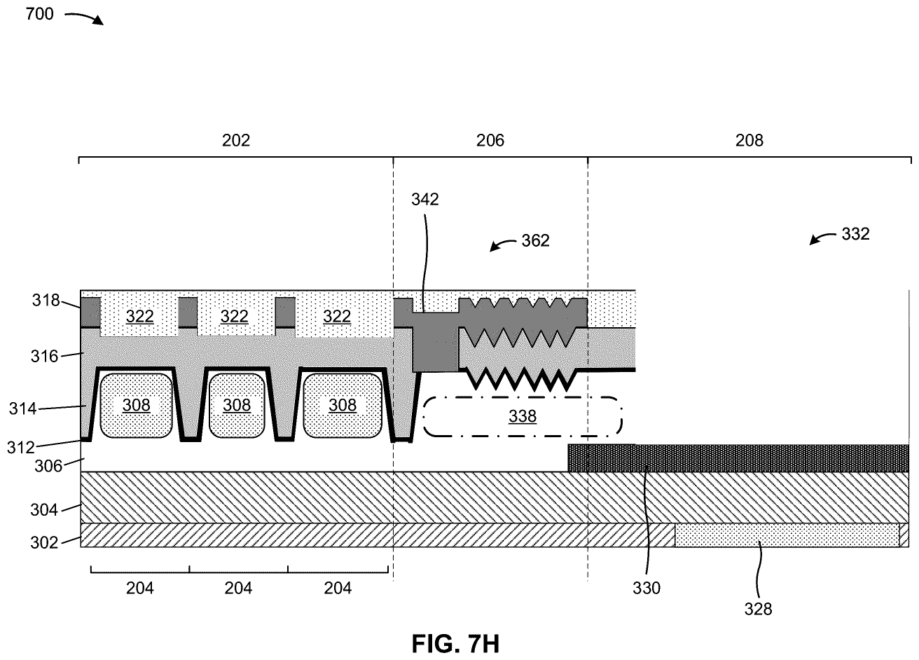

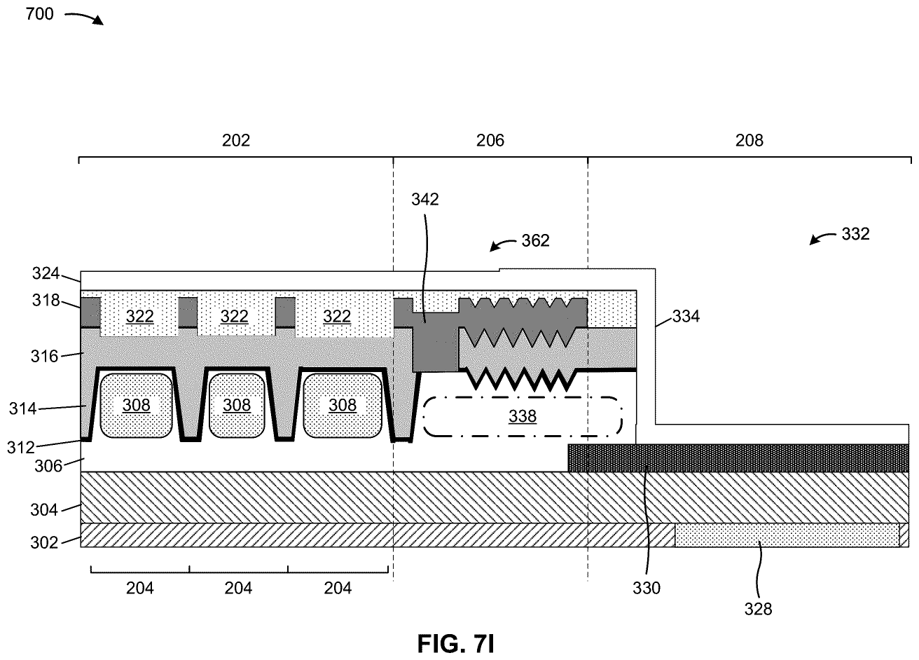

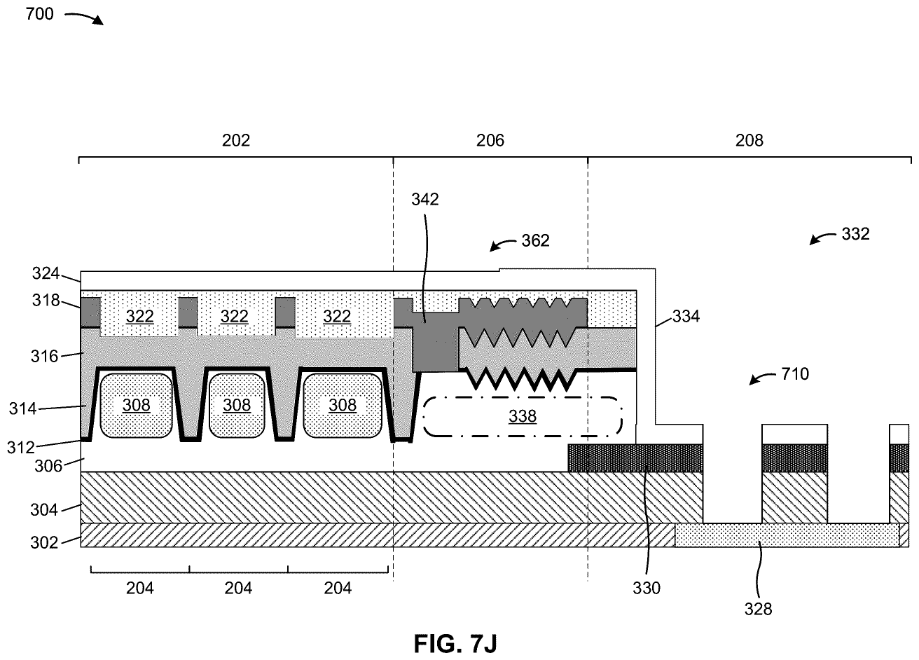

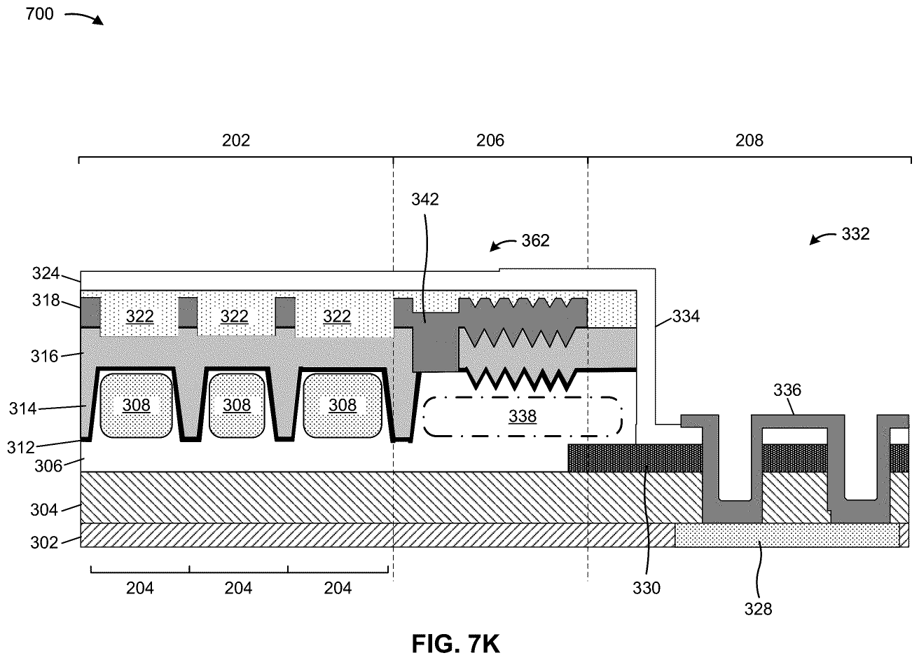

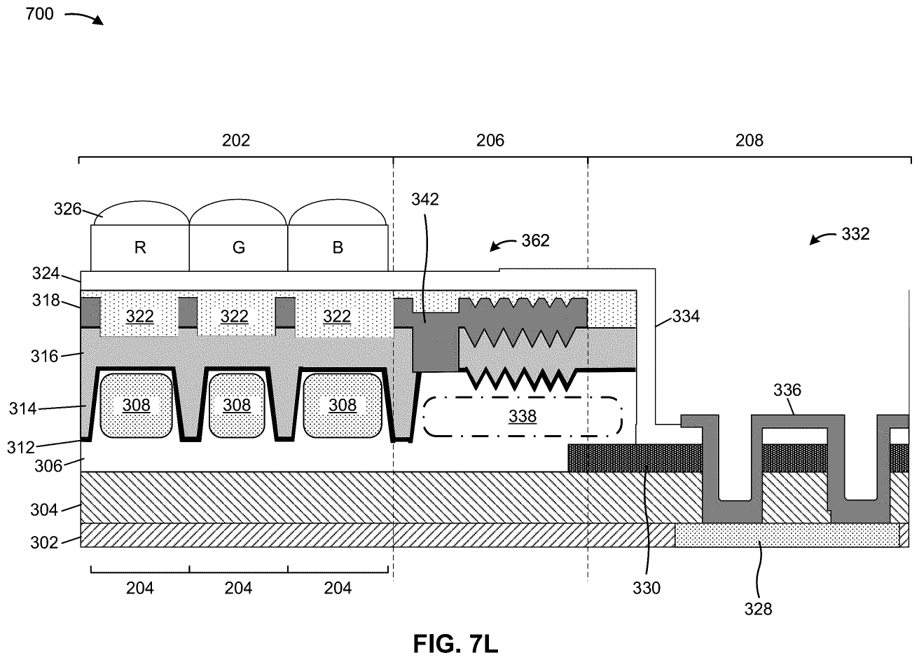

As further shown in FIG. 3C, a portion of the adhesion layer 316 in the optical blocking region 206 conforms to the recessed pattern 362. As a result, and as described in connection with FIG. 7E, a portion of the metal layer 318 in the optical blocking region 206 will follow the recessed pattern 362 during deposition. Additionally, a portion of the substrate 306 (and the ARC 312 over the substrate) in the optical blocking region 206 conforms to the recessed pattern 362. As a result, and as described in connection with FIG. 7C, a portion of the adhesion layer 316 in the optical blocking region 206 will follow the recessed pattern 362 during deposition.

As further shown by reference number 364, the recessed pattern 362 is caused by a plurality of HA structures formed in the substrate 306, and each HA structure is associated with an angle (e.g., an angle with a horizontal axis, represented by θ in FIG. 3C) in a range from approximately 54 degrees to approximately 55 degrees (in one particular example, 54.7°). Selecting an angle in this range preserves the crystalline structure of silicon of the substrate 306, which prevents dangling bonds that could electrically interfere with the pixel sensor array 202. However, other angles are within the scope of the present disclosure (e.g., when using different crystal structures and/or materials for the substrate 306). Additionally, each HA structure may have a spacing relative to an adjacent HA structure (e.g., at top surfaces of the HA structures and represented by s in FIG. 3A). The spacing may be in a range from approximately 0.1 nm to approximately 1.0 nm. Selecting a spacing of at least 0.1 nm prevents the HA structures from merging; merged HA structures would reduce roughness of the metal layer 318 such that light is more likely to pass into the pixel sensor array 202. Selecting a spacing of no more than 1.0 nm increases a density of the HA structures such that the metal layer 318 exhibits increased roughness and is therefore more likely to reflect light rather than pass light into the pixel sensor array 202. However, other spacings are within the scope of the present disclosure.

FIG. 3D is a diagram of a cross-sectional view of an example image sensor device 370 described herein. The cross-section is shown along the line A-A in FIG. 2. FIG. 3D is similar to FIG. 3A except that the optical blocking region 206 includes a recessed pattern 372 in metal (e.g., a portion of the metal layer 318 in the optical blocking region 206) that functions as a light-blocking region to prevent light from entering the sensing region 338. This enables the sensing region 338 to generate a dark current measurement for black level correction (or black level calibration) for the pixel sensor array 202.

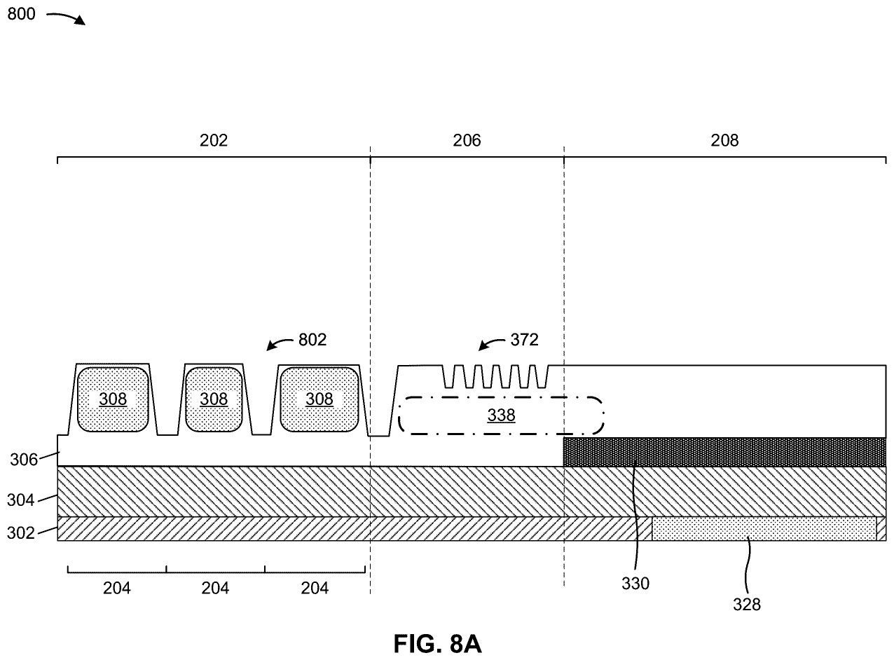

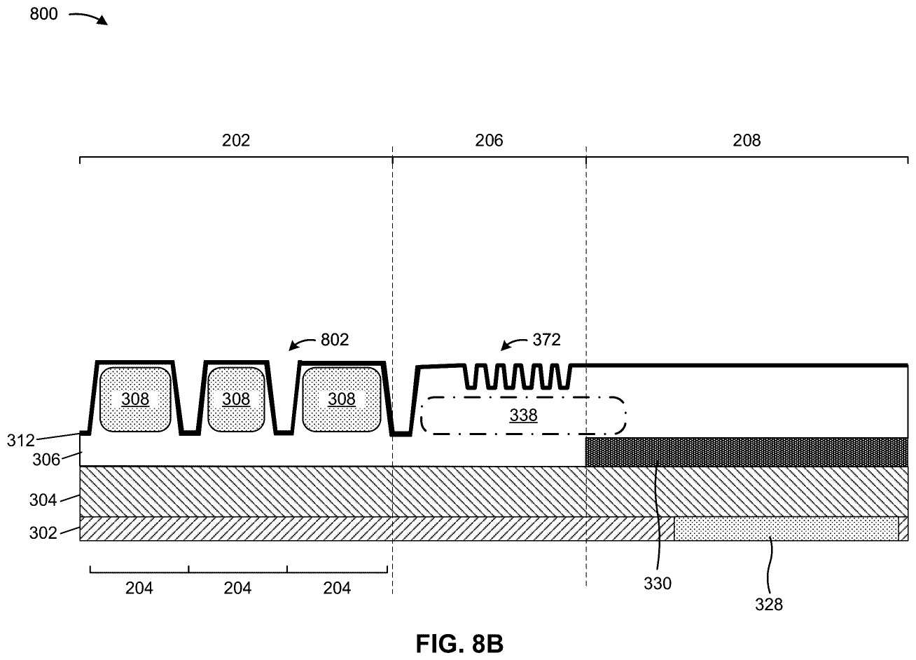

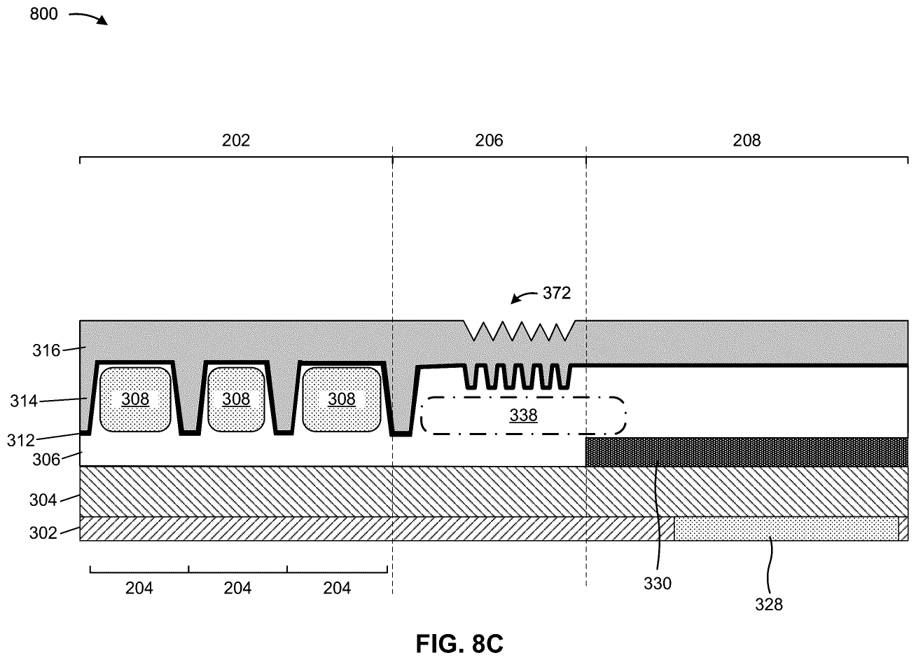

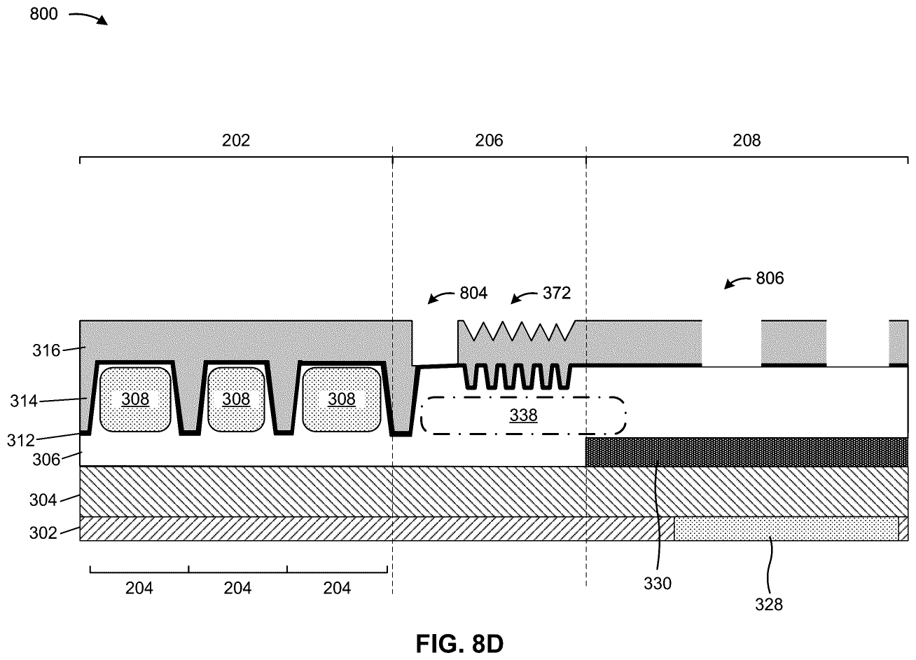

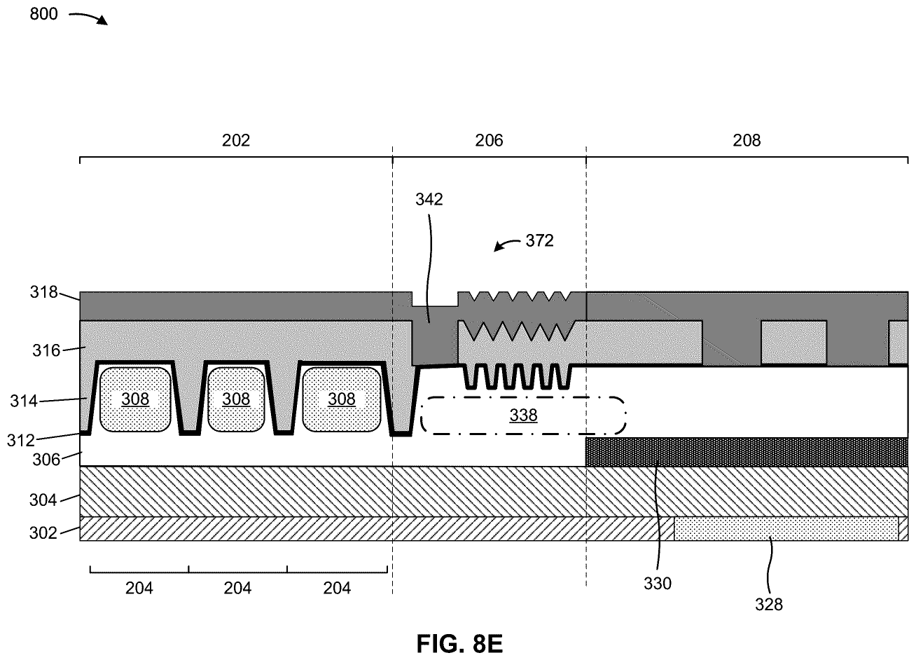

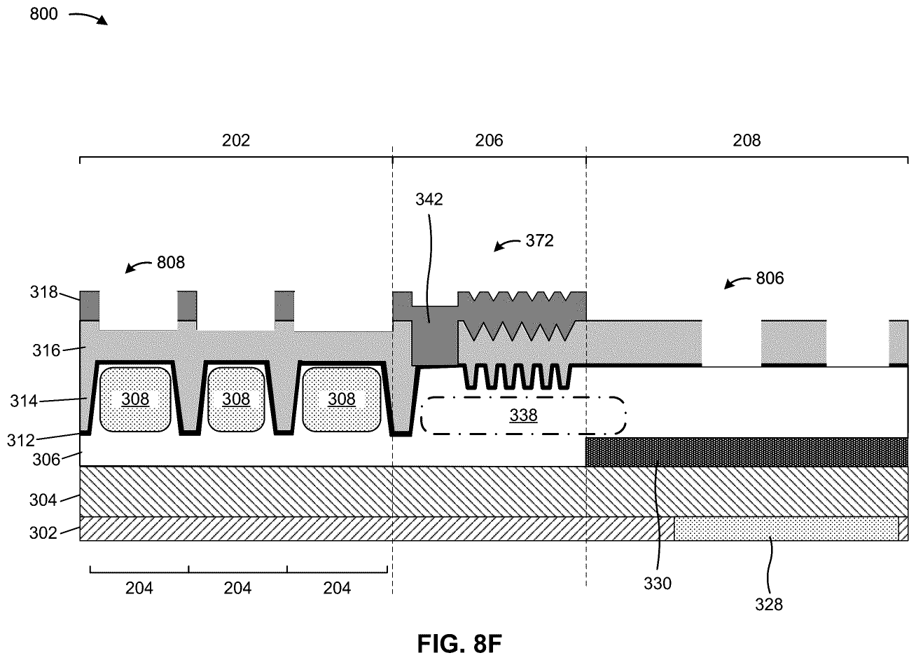

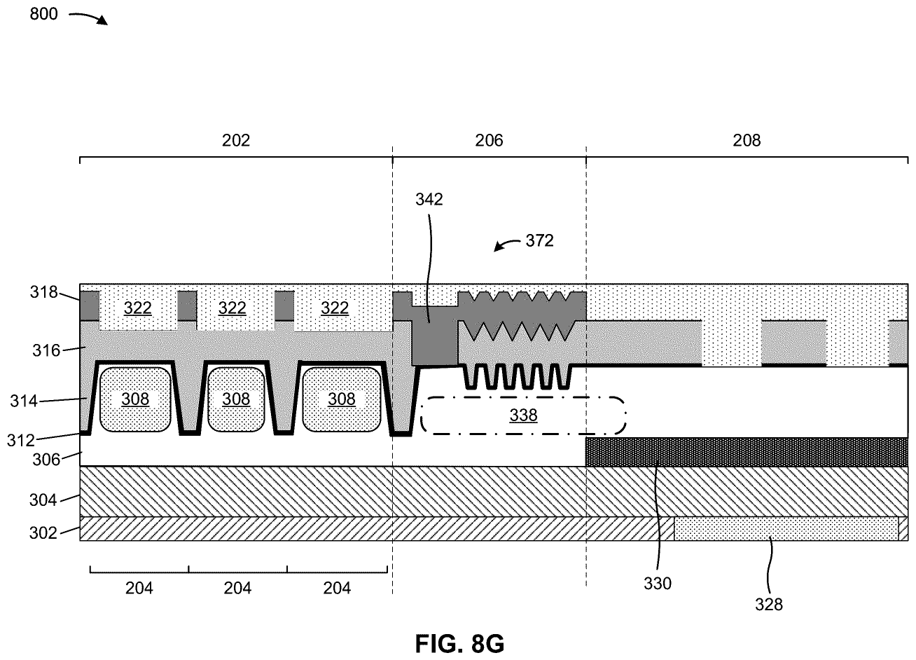

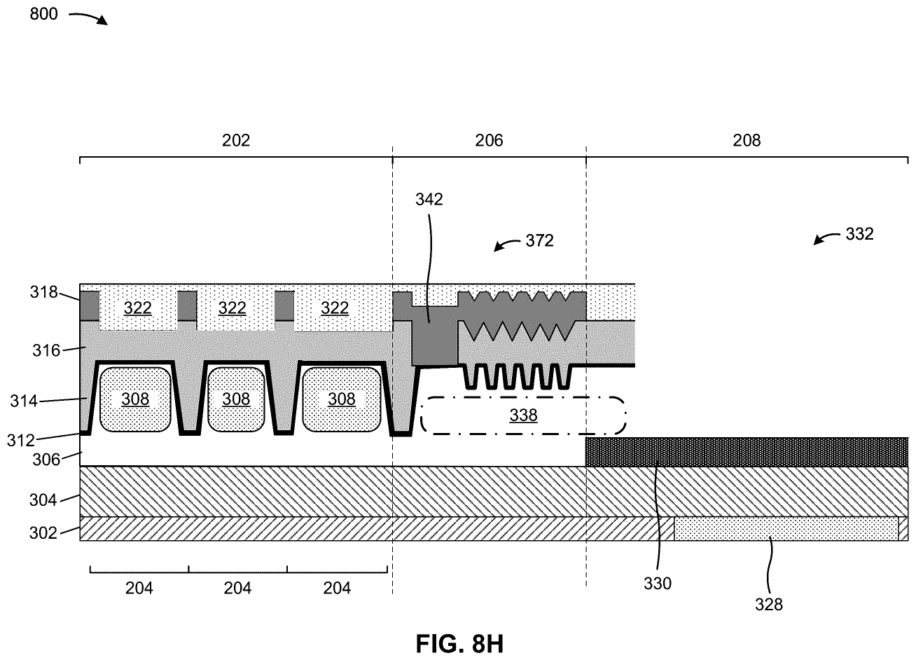

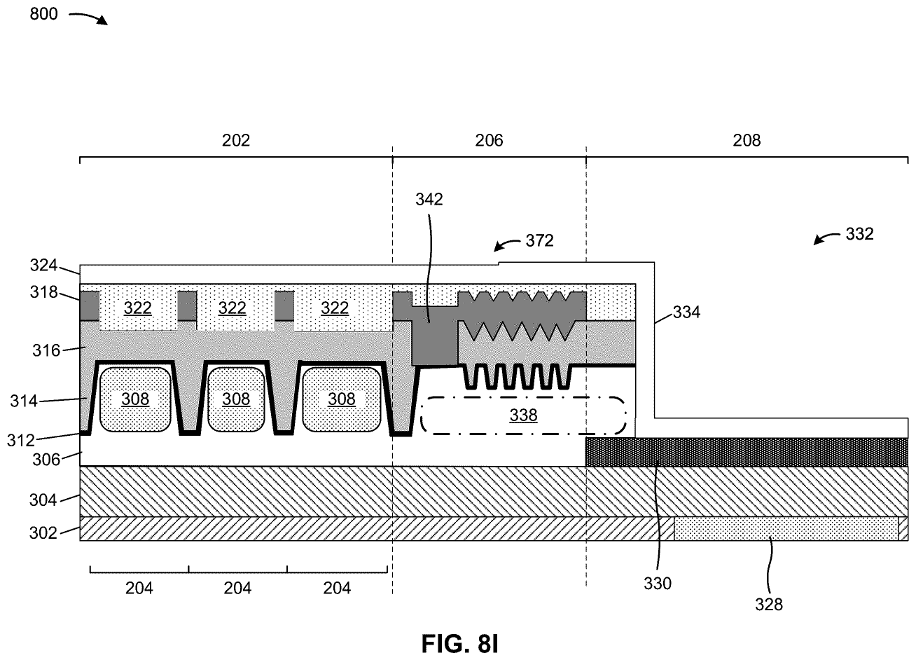

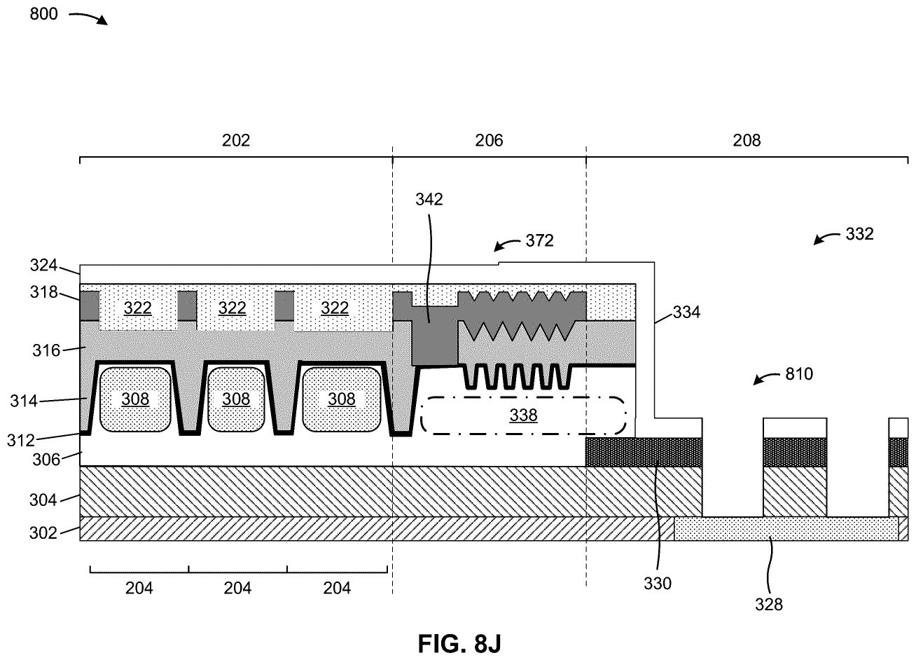

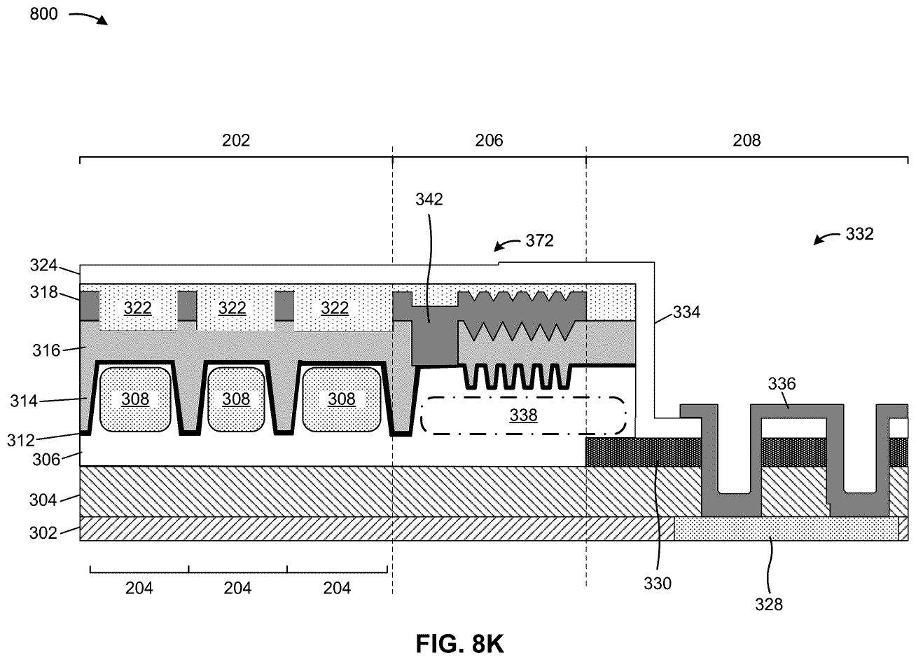

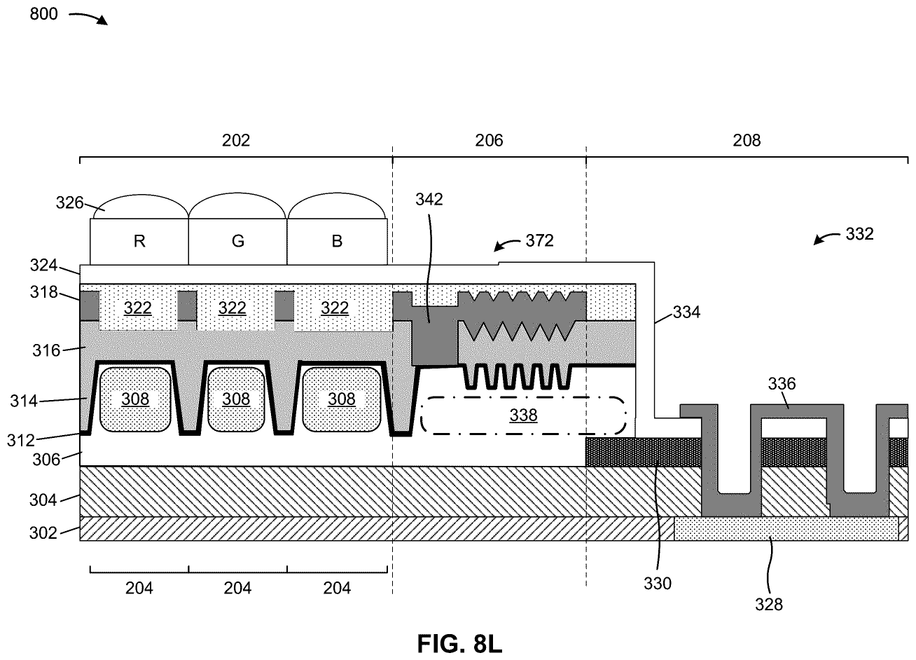

As further shown in FIG. 3D, a portion of the adhesion layer 316 in the optical blocking region 206 conforms to the recessed pattern 372. As a result, and as described in connection with FIG. 8E, a portion of the metal layer 318 in the optical blocking region 206 will follow the recessed pattern 372 during deposition. Additionally, a portion of the substrate 306 (and the ARC 312 over the substrate) in the optical blocking region 206 conforms to the recessed pattern 372. As a result, and as described in connection with FIG. 8C, a portion of the adhesion layer 316 in the optical blocking region 206 will follow the recessed pattern 372 during deposition.

As further shown in FIG. 3D, the recessed pattern 372 is caused by a plurality of shallow isolation structures 374 (e.g., shallow DTI structures) formed in the substrate 306. Each shallow isolation structure may have a depth (e.g., represented by d in FIG. 3D), relative to a top surface of the substrate 306, that is smaller than a depth of the isolation structure 310 relative to the top surface of the substrate 306. As a result, the shallow isolation structures 374 preserve the sensing region 338, which improves accuracy of a dark current measurement for black level correction (or black level calibration) for the pixel sensor array 202. Additionally, each shallow isolation structure may have a width (e.g., represented by w in FIG. 3D) in a range from approximately 100 nm to approximately 400 nm. Selecting a width of at least 100 nm results in increased depths (due to etching processes) of the shallow isolation structures such that the metal layer 318 exhibits increased roughness and is therefore more likely to reflect light rather than pass light into the pixel sensor array 202. Selecting a width of no more than 400 nm increases a density of the shallow isolation structures such that the metal layer 318 exhibits increased roughness and is therefore more likely to reflect light rather than pass light into the pixel sensor array 202. However, other widths are within the scope of the present disclosure.

As indicated above, FIGS. 3A-3D are provided as examples. Other examples may differ from what is described with regard to FIGS. 3A-3D.

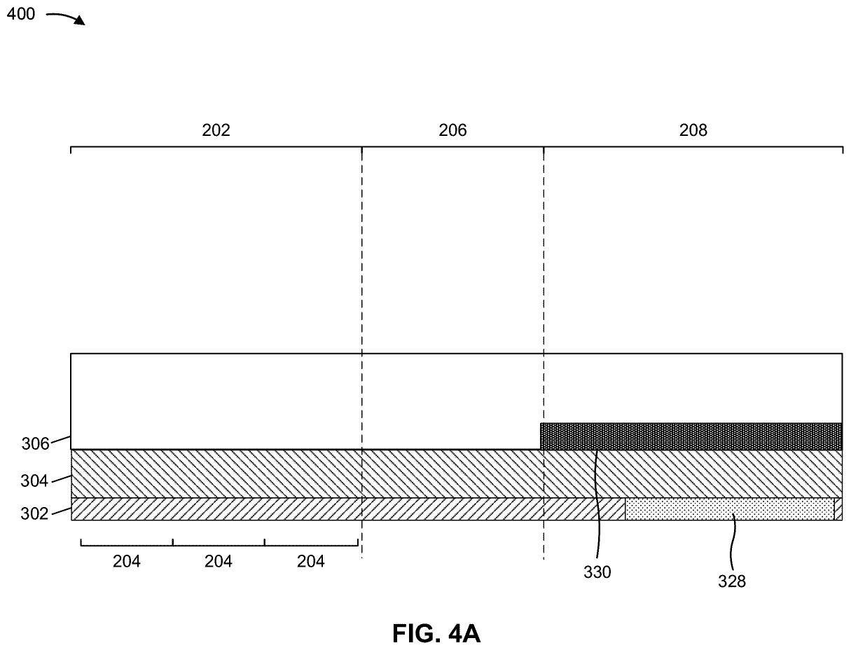

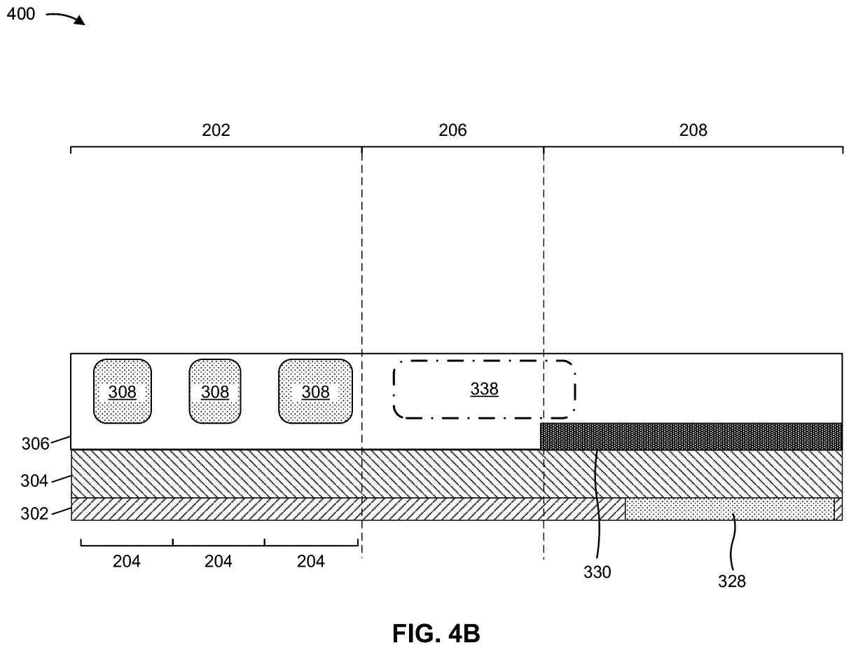

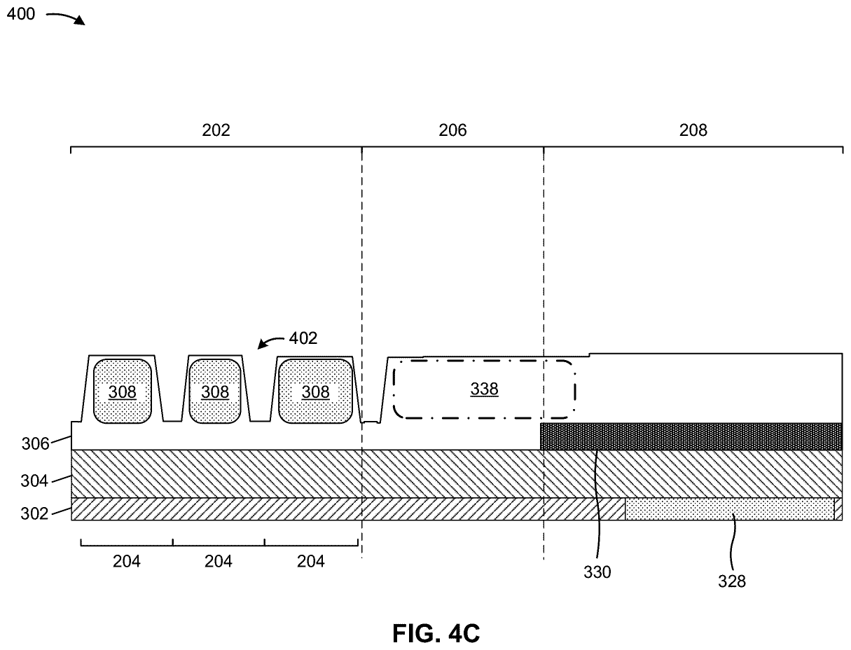

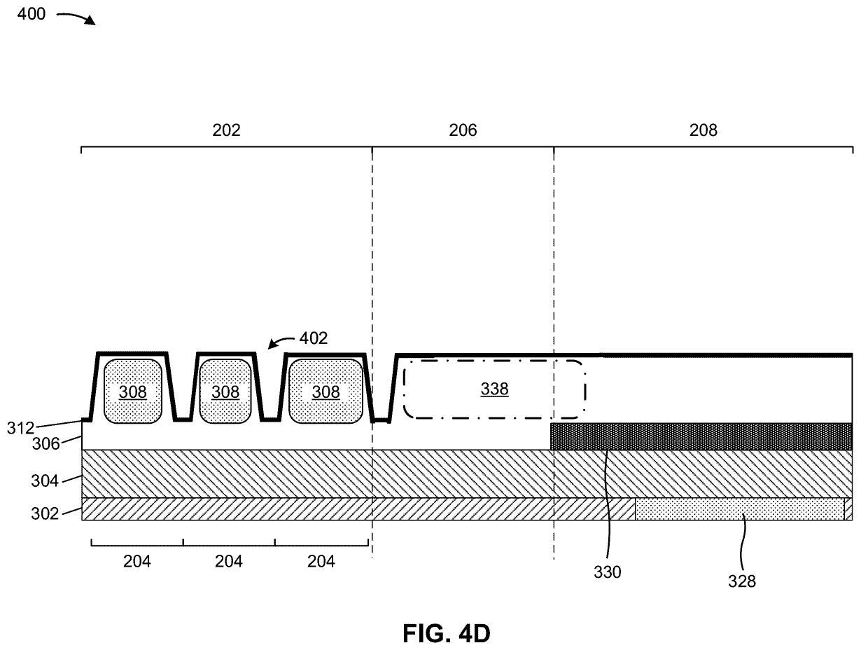

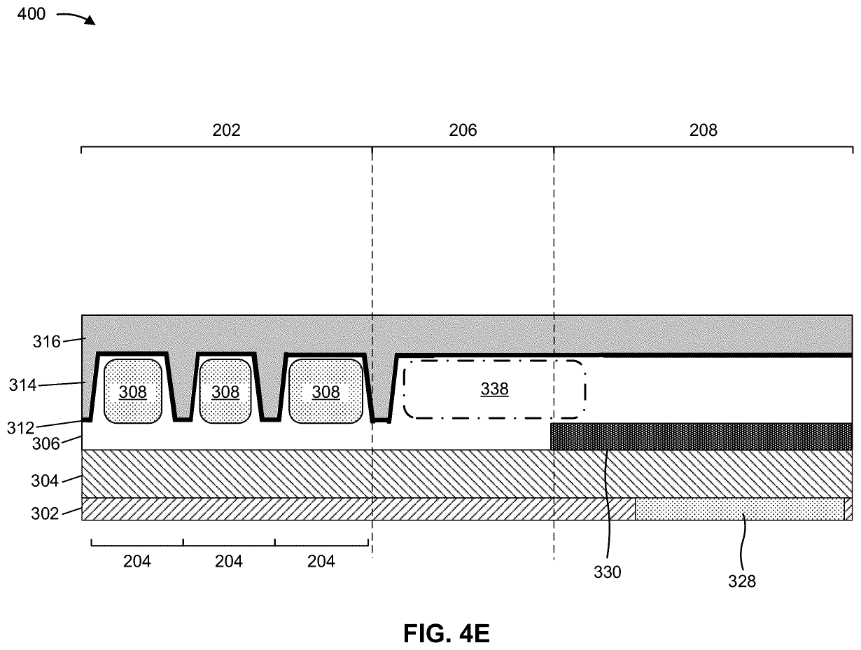

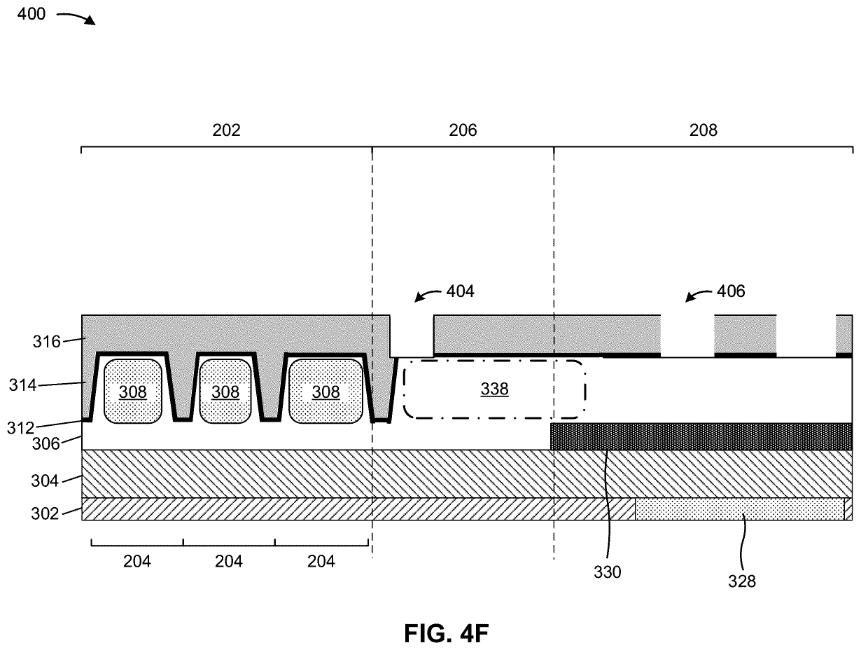

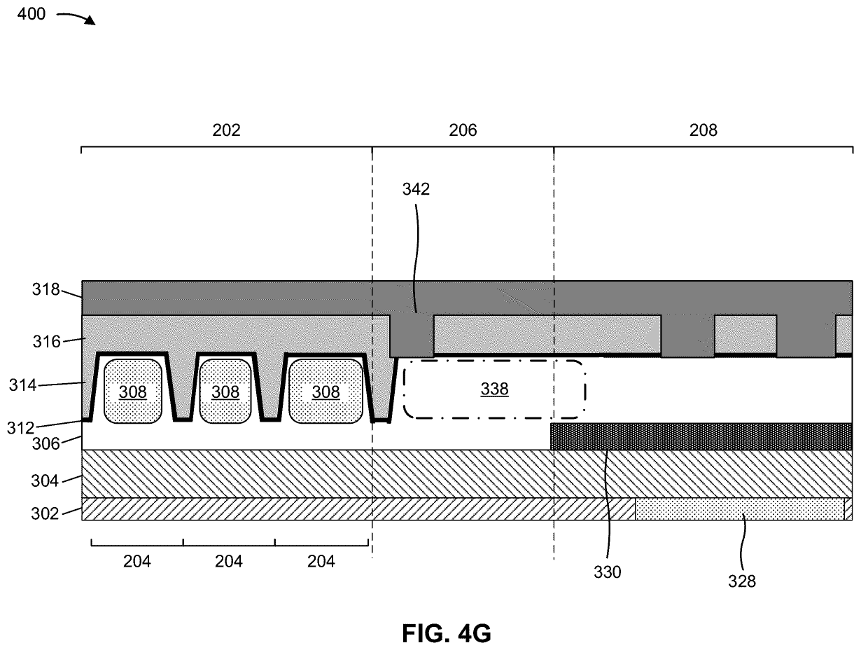

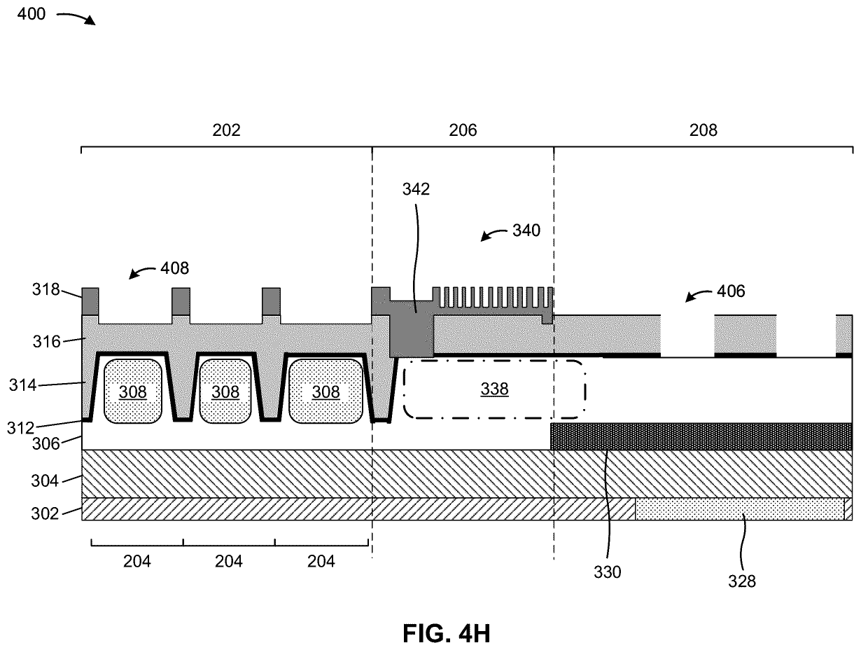

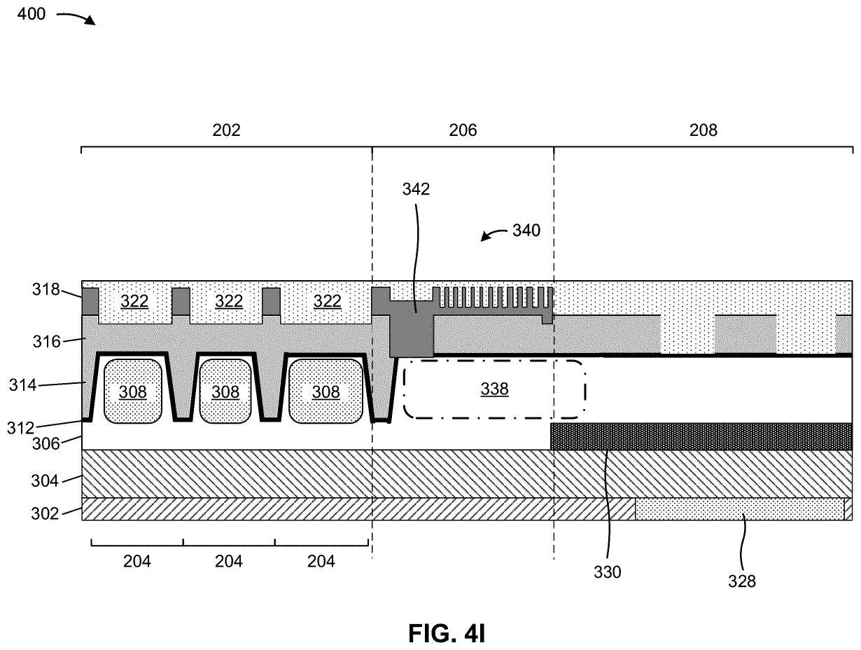

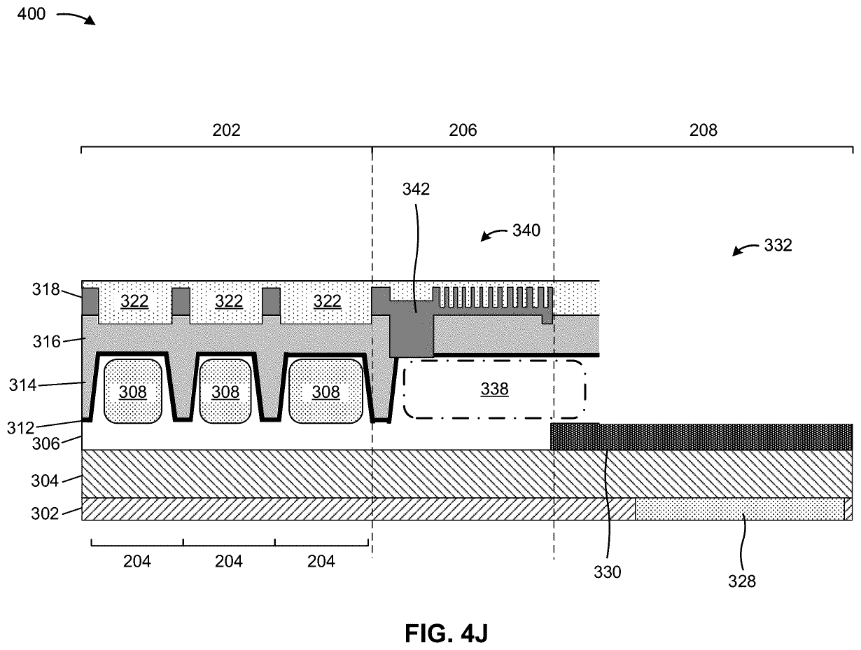

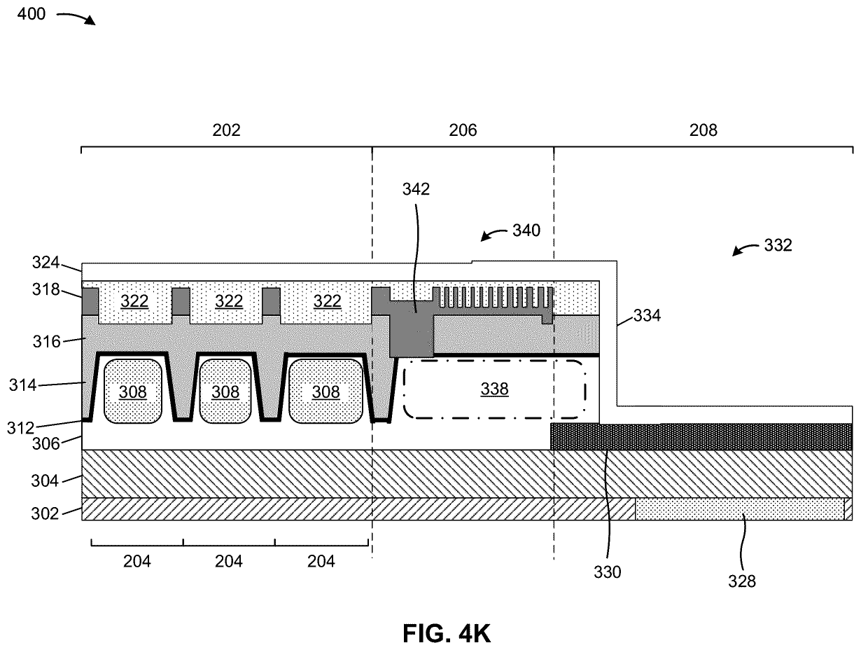

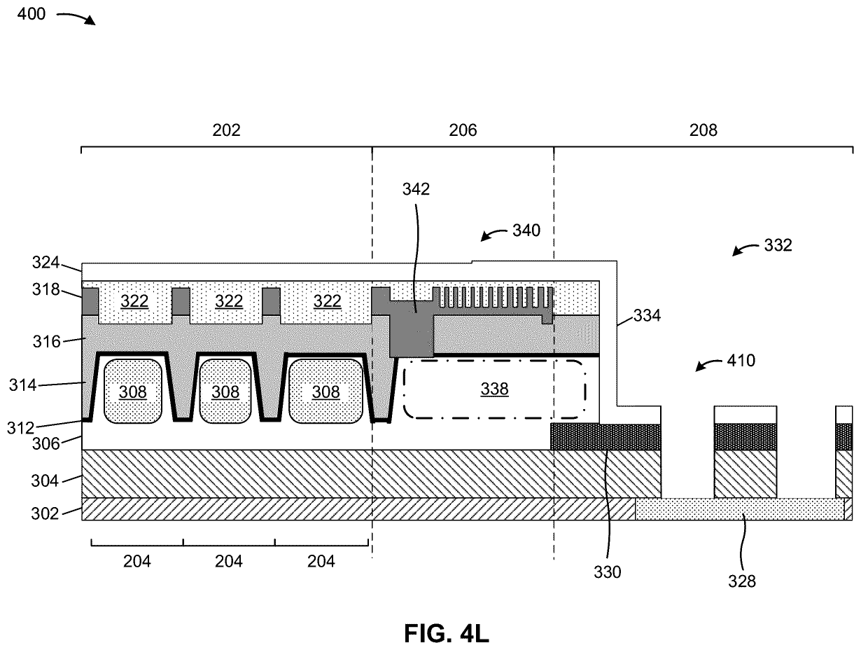

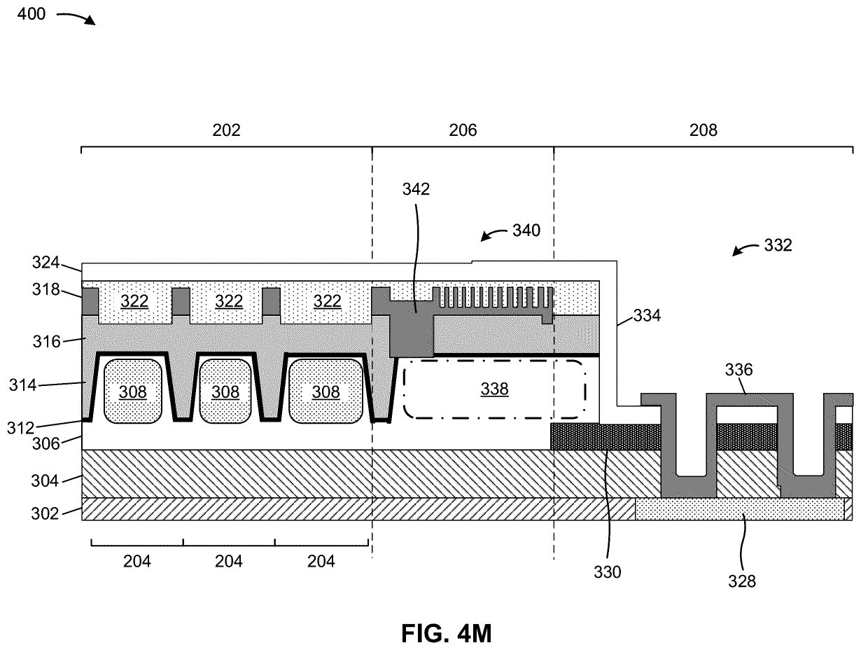

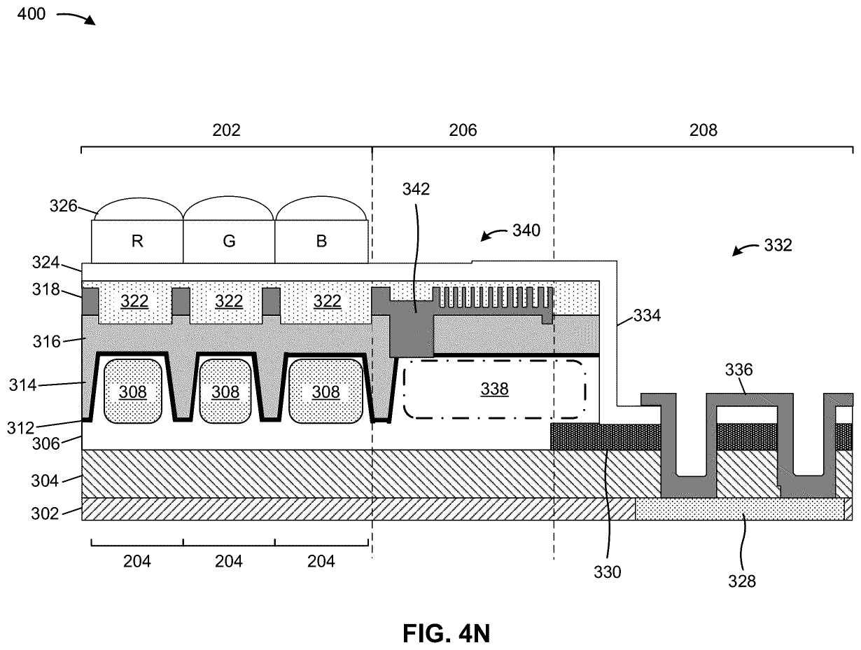

FIGS. 4A-4N are diagrams of an example implementation 400 described herein.

Example implementation 400 may be an example process for forming an example image sensor device 300 described herein. The example image sensor device 300 may include a pixel sensor array 202 including a plurality of pixel sensors 204, an optical blocking region 206 including a nanoscale metal grid 340, and an electrical pad region 208, among other examples. In the example implementation 400, the electrical pad region 208 is formed after the nanoscale metal grid 340.

As shown in FIG. 4A, the example image sensor device 300 may include a plurality of layers, including an IMD layer 302, an ILD layer 304, and a substrate 306, among other examples. In some implementations, the substrate 306 may be provided as a semiconductor wafer or another type of semiconductor work piece. In some implementations, the deposition tool 102 may deposit the IMD layer 302 and/or the ILD layer 304 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the IMD layer 302 and/or the ILD layer 304 after the deposition tool 102 deposits the IMD layer 302 and/or the ILD layer 304.

As further shown in FIG. 4A, a metallization layer 328 may be formed in the IMD layer 302. The IMD layer 302 may be formed in the electrical pad region 208 of the example image sensor device 300. In some implementations, the etch tool 108 may form a recess in the IMD layer 302, and the metallization layer 328 may be formed in the recess. The deposition tool 102 and/or the plating tool 112 may deposit the metallization layer 328 in a CVD operation, a PVD operation, an ALD operation, an electroplating operation, another deposition operation described above in connection with FIG. 1, and/or another suitable deposition operation. In some implementations, a seed layer is first deposited, and the metallization layer 328 is deposited on the seed layer. In some implementations, the planarization tool 110 planarizes the metallization layer 328 after the deposition tool 102 and/or the plating tool 112 deposits the metallization layer 328.

As further shown in FIG. 4A, an STI region 330 may be formed in the substrate 306 (e.g., prior to formation of the IMD layer 302 and/or the ILD layer 304). The STI region 330 may be formed in the electrical pad region 208 of the example image sensor device 300. In some implementations, the deposition tool 102 may deposit the STI region 330 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the STI region 330 after the deposition tool 102 deposits the STI region 330. In some implementations, the etch tool 108 may form a recess in the substrate 306, and the STI region 330 may be formed in the recess.

As shown in FIG. 4B, a plurality of photodiodes 308 may be formed in the substrate 306. For example, an ion implantation tool may dope portions of the substrate 306 using an ion implantation technique to form a respective photodiode 308 for a plurality of pixel sensors 204. The substrate 306 may be doped with a plurality of types of ions to form a p-n junction for each photodiode 308. For example, the substrate 306 may be doped with an n-type dopant to form a first portion (e.g., an n-type portion) of a photodiode 308 and a p-type dopant to form a second portion (e.g., a p-type portion) of the photodiode 308. In some implementations, another technique is used to form the photodiodes 308 such as diffusion.

As further shown in FIG. 4B, a sensing region 338 may be included in the substrate 306 in the optical blocking region 206 adjacent to the pixel sensors 204 of the pixel sensor array 202. In some implementations, the sensing region 338 includes an undoped portion of the substrate 306 in the optical blocking region 206. In some implementations, an ion implantation tool may dope the portions of the substrate 306 using an ion implantation technique to form the sensing region 338.

As shown in FIG. 4C, recesses 402 may be formed in the substrate 306 around the photodiodes 308 in the pixel sensor array 202. The recesses 402 may be formed as part of forming an isolation structure 310 in the substrate 306 around the photodiodes 308 of the pixel sensors 204 in the pixel sensor array 202. In some implementations, the deposition tool 102 may form a photoresist layer on the substrate 306, the exposure tool 104 may expose the photoresist layer to a radiation source to pattern the photoresist layer, the developer tool 106 may develop and remove portions of the photoresist layer to expose the pattern, and the etch tool 108 may etch portions of substrate 306 to form the recesses 402 for the isolation structure 310 in the substrate 306. In some implementations, the photoresist removal tool 114 removes the remaining portions of the photoresist layer (e.g., using a chemical stripper and/or another technique) after the etch tool 108 etches the substrate 306.

As shown in FIG. 4D, an ARC 312 may be formed above and/or on the substrate 306 as well as in the recesses 402. The ARC 312 may be conformally deposited such that the ARC 312 includes a thin film that conforms to the shape and/or profile of the recesses 402. The ARC 312 may be included on the surface of the substrate 306 in the pixel sensor array 202, in the optical blocking region 206, and/or in the electrical pad region 208, among other examples. The deposition tool 102 may deposit the ARC 312 using a CVD technique, a PVD technique, an ALD technique, or another type of deposition technique.

As shown in FIG. 4E, the recesses 402 may be filled with a dielectric layer 314. Additional dielectric material may be deposited such that an adhesion layer 316 extends along the surface of the substrate 306 in the pixel sensor array 202, in the optical blocking region 206, and in the electrical pad region 208, among other examples. The deposition tool 102 may deposit the dielectric layer 314 using various CVD techniques and/or ALD techniques, such as PECVD, HDP-CVD, SACVD, and/or PEALD, among other examples.

As shown in FIG. 4F, a recess 404 may be formed in the adhesion layer 316 at a portion of the optical blocking region 206 at (or near) a boundary with the pixel sensor array 202. The recess 404 may be formed as part of forming a grounding node 342. Accordingly, the recess 404 may expose a top surface of the substrate 306. In some implementations, the deposition tool 102 may form a photoresist layer on the adhesion layer 316, the exposure tool 104 may expose the photoresist layer to a radiation source to pattern the photoresist layer, the developer tool 106 may develop and remove portions of the photoresist layer to expose the pattern, and the etch tool 108 may etch portions of adhesion layer 316 to form the recess 404 for the grounding node 342 in the adhesion layer 316. In some implementations, the photoresist removal tool 114 removes the remaining portions of the photoresist layer (e.g., using a chemical stripper and/or another technique) after the etch tool 108 etches the adhesion layer 316.

In some implementations, as further shown in FIG. 4F, recesses 406 may be formed in the adhesion layer 316 in the electrical pad region 208. The recesses 406 may be formed as part of forming an electrical pad 336. Accordingly, the recesses 406 may expose a top surface of the substrate 306. In some implementations, the pattern exposed by the developer tool 106 may be used to form both the recess 404 and the recesses 406. Alternatively, the adhesion layer 316 may be etched in the electrical pad region 208 during a later etching cycle (e.g., the etching cycle as described in connection with FIG. 4J).

As shown in FIG. 4G, a metal layer 318 may be formed over and/or on the adhesion layer 316. The metal layer 318 may be formed in the pixel sensor array 202, in the optical blocking region 206, and in the electrical pad region 208, among other examples. The portion of the metal layer 318 in the optical blocking region 206 may correspond to a light-blocking layer for the sensing region 338. Additionally, the metal layer 318 may fill the recess 402 to form the grounding node 342. The deposition tool 102 and/or the plating tool 112 may deposit the metal layer 318 in a CVD operation, a PVD operation, an ALD operation, an electroplating operation, another deposition operation described above in connection with FIG. 1, and/or another suitable deposition operation. In some implementations, a seed layer is first deposited, and the metal layer 318 is deposited on the seed layer. In some implementations, the planarization tool 110 planarizes the metal layer 318 after the deposition tool 102 and/or the plating tool 112 deposits the metal layer 318.

As shown in FIG. 4H, openings 408 may be formed through the metal layer 318 in the pixel sensor array 202. The openings 408 may be formed over the photodiodes 308 of the pixel sensors 204 in the pixel sensor array 202. The openings 408 may be formed by removing first portions of the metal layer 318 to form a metal grid 320 above the isolation structure 310. The openings 408 and the metal grid 320 may be formed while the optical blocking region 206 and the electrical pad region 208 are masked (e.g., by a photoresist layer or a hard mask). In some implementations, the deposition tool 102 may form a photoresist layer on the metal layer 318 in the pixel sensor array 202, the exposure tool 104 may expose the photoresist layer to a radiation source to pattern the photoresist layer, the developer tool 106 may develop and remove portions of the photoresist layer to expose the pattern, and the etch tool 108 may etch through portions of the metal layer 318 to form the openings 408. In some implementations, the etch tool 108 etches into a portion of the underlying adhesion layer 316 to ensure that the metal layer 318 is fully etched through. The portions of the underlying adhesion layer 316 that are removed may be referred to as over-etch regions. In some implementations, the photoresist removal tool 114 removes the remaining portions of the photoresist layer (e.g., using a chemical stripper and/or another technique) after the etch tool 108 etches the metal layer 318.

As further shown in FIG. 4H, the metal layer 318 may be patterned into a nanoscale metal grid 340 in the optical blocking region 206. As described in connection with FIG. 3A, the nanoscale metal grid 340 includes a plurality of metal structures, and each metal structure has a width in a range from approximately 100 nm to approximately 200 nm.

In some implementations, the nanoscale metal grid 340 may be formed using double pattern lithography in order to etch nanoscale openings between the metal structures. The nanoscale metal grid 340 may be formed while the pixel sensor array 202 and the electrical pad region 208 are masked (e.g., by a photoresist layer or a hard mask). Alternatively, a same process (e.g., the double pattern lithography) may be used to form the metal grid 320 and the nanoscale metal grid 340. The nanoscale metal grid 340 reduces the likelihood of light being reflected from the optical blocking region 206 and toward the pixel sensor array 202. In this way, the nanoscale metal grid 340 reduces a likelihood of occurrence of flares or hot spots in images and/or videos generated by the example image sensor device 300, which increases image quality. The nanoscale metal grid 340 remains at an electrical neutral via the grounding node 342, even as photons collide with the nanoscale metal grid 340. As a result, current does not leak from the nanoscale metal grid 340 to the pixel sensor array 202, which improves performance of the example image sensor device 300.

In some implementations, as further shown in FIG. 4H, the recesses 406 may be re-opened in the metal layer 318 in the electrical pad region 208. The recesses 406 may be formed as part of forming the metal grid 320 and the nanoscale metal grid 340 (e.g., using double pattern lithography). Alternatively, the metal layer 318 may be etched in the electrical pad region 208 during a later etching cycle (e.g., the etching cycle as described in connection with FIG. 4J).

As shown in FIG. 4I, respective color filter regions 322 may be formed in the openings 408 for each of the pixel sensors 204 in the pixel sensor array 202. Each color filter region 322 may be formed in between the metal grid 320 to reduce color mixing between adjacent pixel sensors 204. Additionally, or alternatively, the areas between the metal grid 320 may be filled with a passivation layer, and a color filter layer including the color filter regions 322 may be formed on the passivation layer above the metal grid 320. For example, as shown in FIG. 4I, the passivation layer may further be formed in the optical blocking region 206 and/or the electrical pad region 208. In some implementations, the deposition tool 102 may deposit the color filter regions 322 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the color filter regions 322 after the deposition tool 102 deposits the color filter regions 322.

As shown in FIG. 4J, a recess 332 may be formed in the electrical pad region 208. In particular, the recess 332 may be formed through the passivation layer, through the metal layer 318, through the adhesion layer 316, through the ARC 312, and into the substrate 306 to the STI region 330. The STI region 330 may be exposed through the recess 332. The recess 332 may be formed by coating the passivation layer with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching the recess 332 (e.g., using the etch tool 108) based on the pattern in the photoresist.

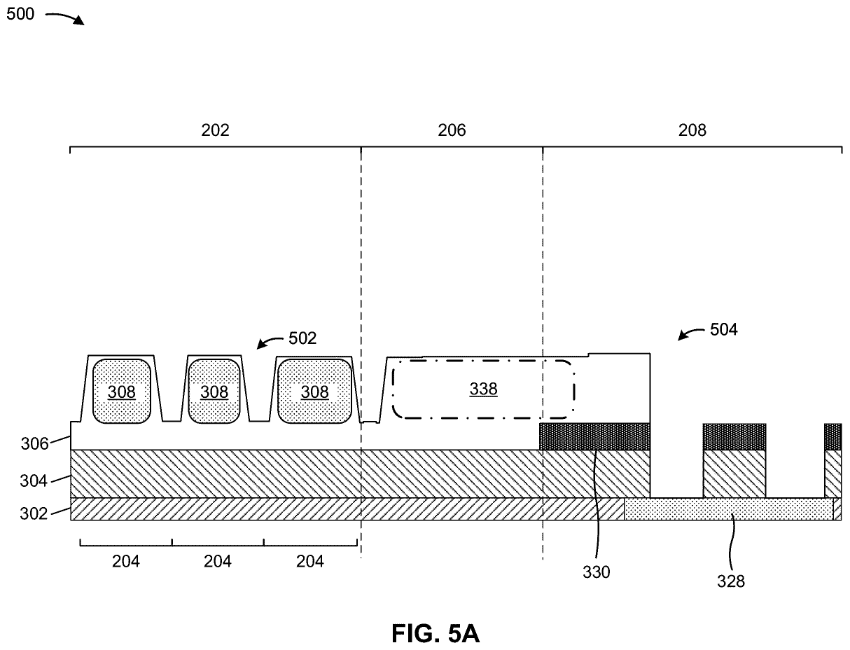

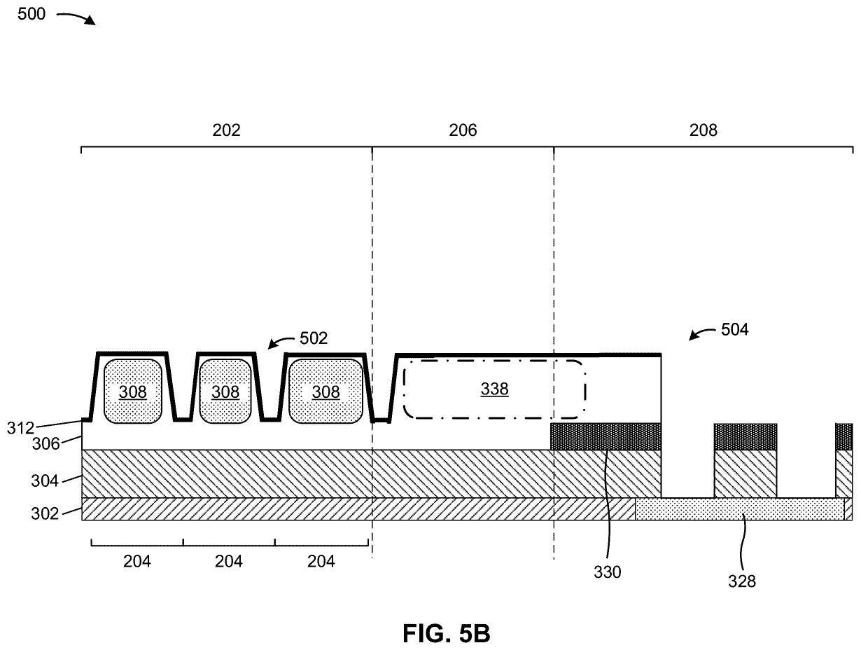

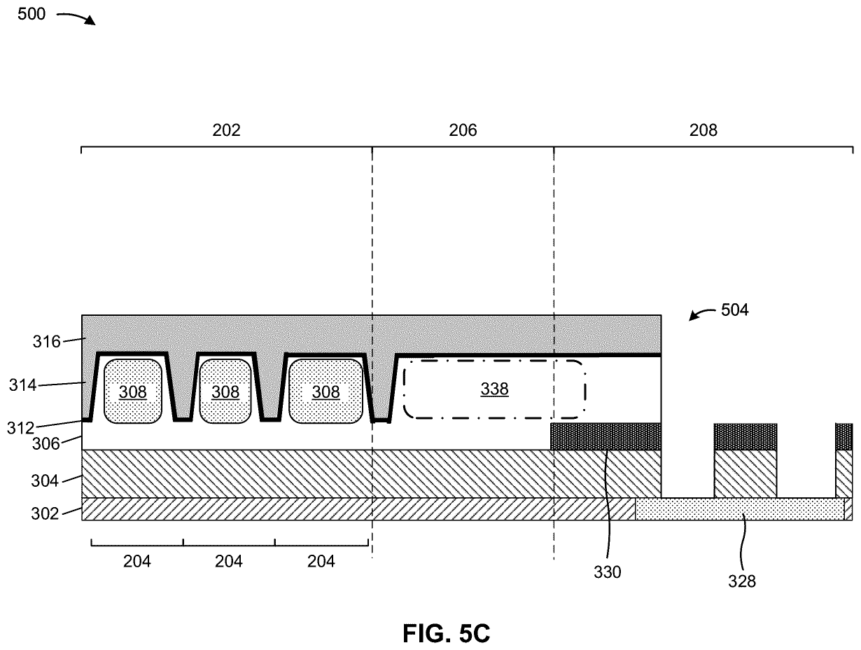

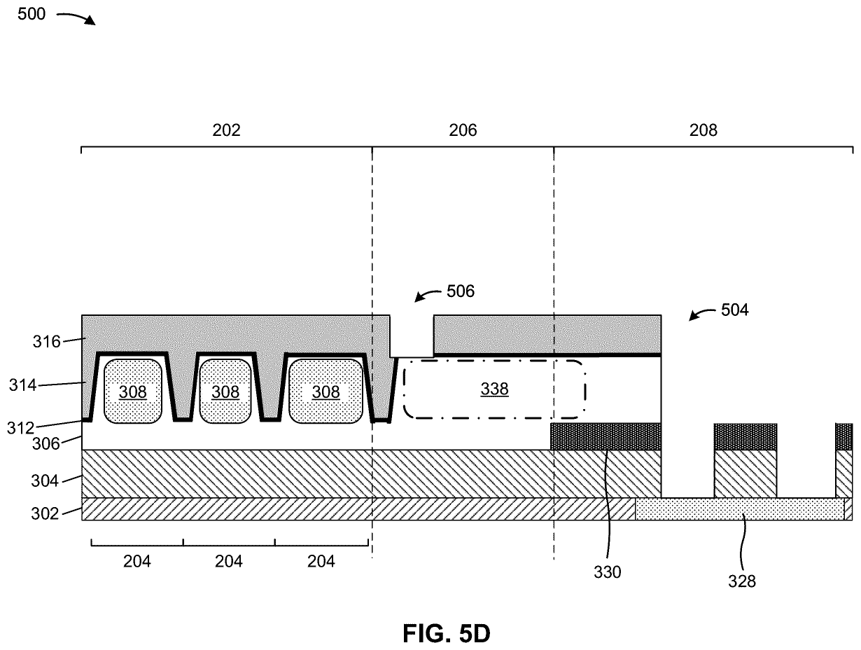

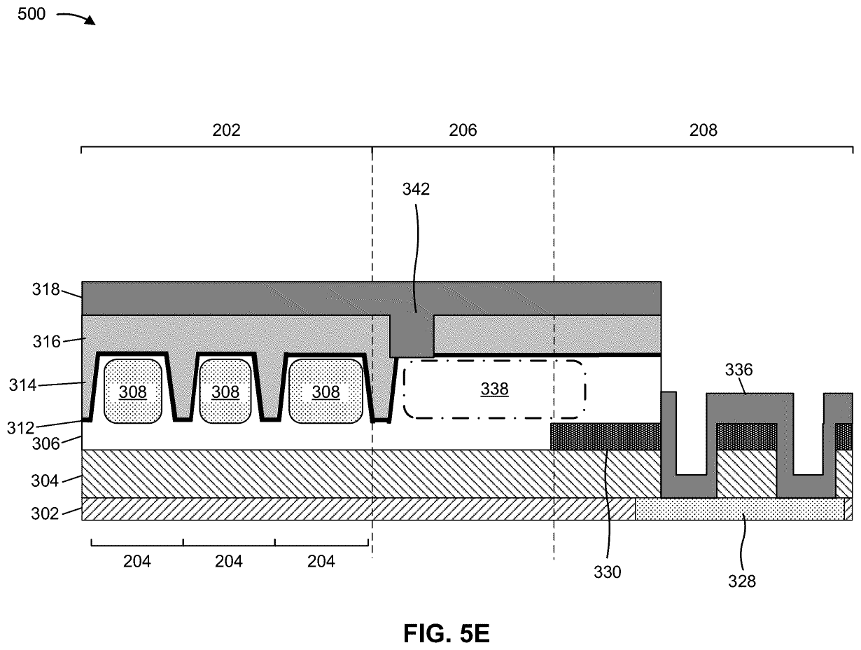

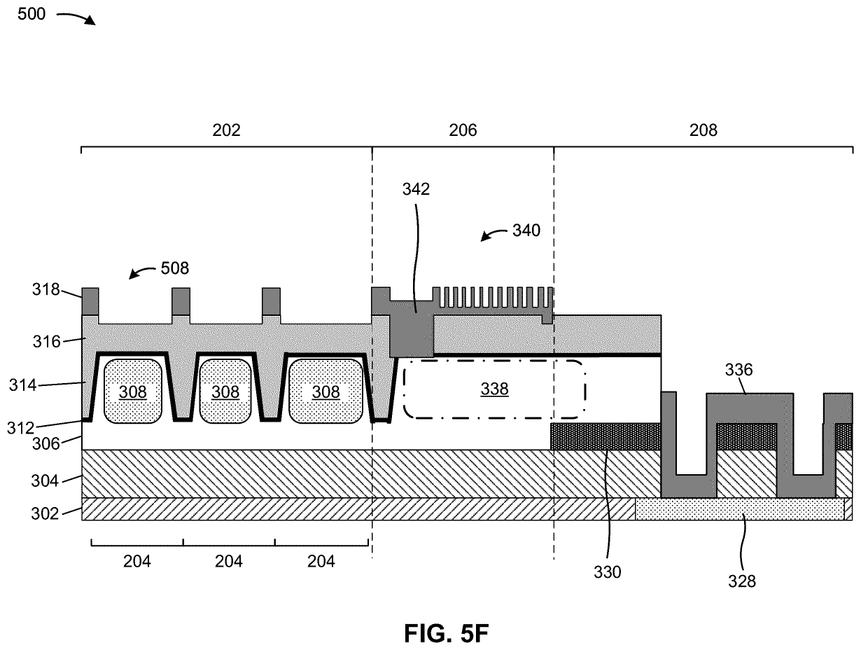

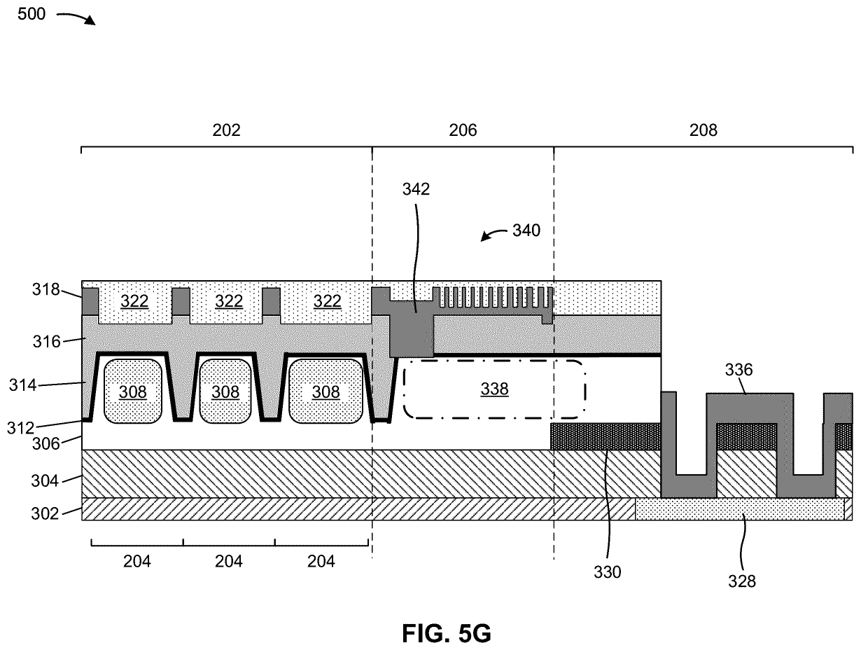

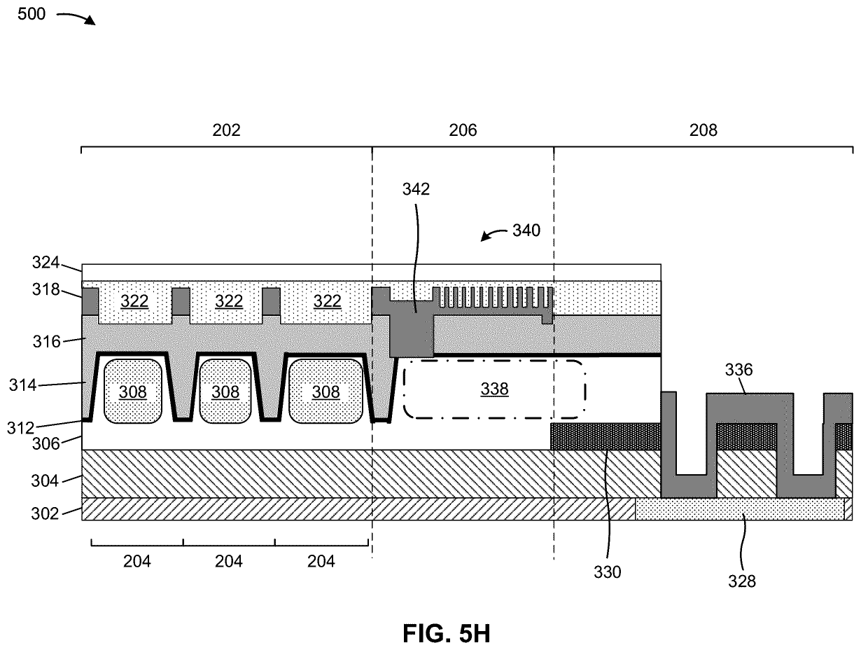

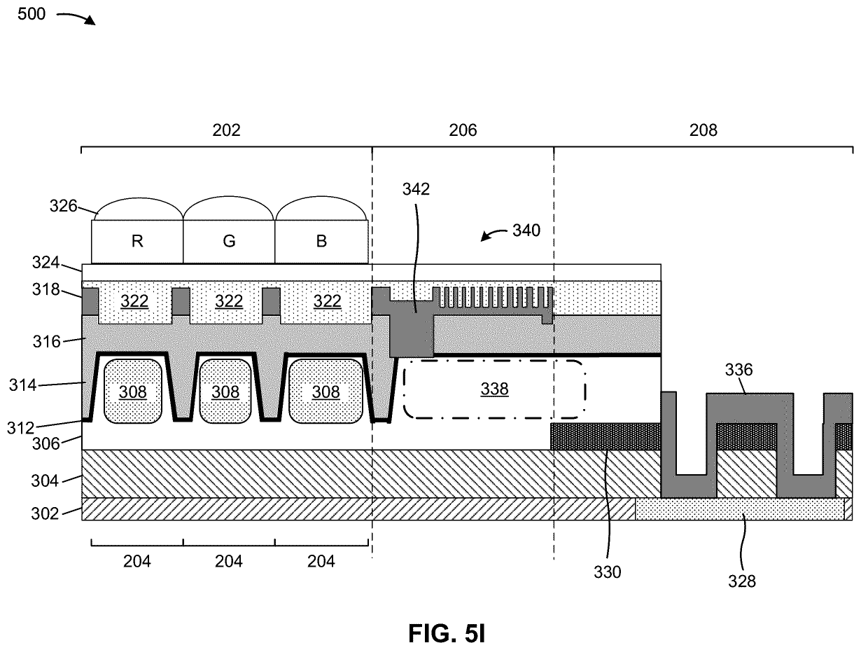

As shown in FIG. 4K, a dielectric layer 324 may be formed over the passivation layer in the pixel sensor array 202 and/or the optical blocking region 206, as well as over the STI region 330 in the electrical pad region 208. The dielectric layer 324 may also be formed on exposed sidewalls of the recess 332. The deposition tool 102 may conformally deposit the dielectric layer 324 using a CVD technique, a PVD technique, an ALD technique, or another type of deposition technique. Other implementations may omit the dielectric layer 324 from the electrical pad region 208 (e.g., as described in connection with FIG. 5I).

As shown in FIG. 4L, openings 410 may be formed in the recess 332 of the electrical pad region 208. In particular, the openings 410 may be formed through the dielectric layer 324 (if present), through the STI region 330, and through the ILD layer 304, to the metallization layer 328 in the IMD layer 302. The openings 410 may be formed by coating the dielectric layer 324 with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching the openings 410 (e.g., using the etch tool 108) based on the pattern in the photoresist.

As shown in FIG. 4M, an electrical pad 336 may be formed in the openings 410. For example, a semiconductor processing tool (e.g., the deposition tool 102 or the plating tool 112) may form a metal layer (e.g., an aluminum layer, a copper layer, a tungsten layer, a gold layer, a silver layer, a metal alloy layer, or another type of metal layer) on the dielectric layer 334 (if present) and on sidewalls of the openings 410, such that portions of the electrical pad 336 land on the metallization layer 328.

As shown in FIG. 4N, a micro-lens layer 326 including a plurality of micro-lenses is formed over and/or on the color filter regions 322. The micro-lens layer 326 may include a respective micro-lens for each of the pixel sensors 204 included in the pixel sensor array 202.

As indicated above, FIGS. 4A-4N are provided as an example. Other examples may differ from what is described with regard to FIGS. 4A-4N. For example, the dielectric layer 324 may be omitted from part, or all, of the example image sensor device 300. Additionally, or alternatively, the color filter regions 322 may be omitted and replaced with only the passivation layer described above.

FIGS. 5A-5I are diagrams of an example implementation 500 described herein. Example implementation 500 may be an example process for forming an example image sensor device 300 described herein. The example image sensor device 300 may include a pixel sensor array 202 including a plurality of pixel sensors 204, an optical blocking region 206 including a nanoscale metal grid 340, and an electrical pad region 208, among other examples. In the example implementation 500, the electrical pad region 208 is formed concurrently with the nanoscale metal grid 340.

As shown in FIG. 5A, the example implementation 500 may include processes described in connection with FIGS. 4A-4C. As further shown in FIG. 5A, recesses 504 may be formed in the electrical pad region 208. The recesses 504 may be formed as part of forming an electrical pad 336. Accordingly, the recesses 504 may expose the STI region 330 as well as a portion of the metallization layer 328 in the IMD layer 302. In some implementations, the pattern exposed by the developer tool 106 may be used to form both the recesses 502 and the recesses 504. Alternatively, the recesses 504 may be etched in the electrical pad region 208 during a later etching cycle (e.g., the etching cycle as described in connection with FIG. 5D).

As shown in FIG. 5B, an ARC 312 may be formed above and/or on the substrate 306 as well as in the recesses 502. The ARC 312 may be conformally deposited such that the ARC 312 includes a thin film that conforms to the shape and/or profile of the recesses 502. The ARC 312 may be included on the surface of the substrate 306 in the pixel sensor array 202 and/or in the optical blocking region 206. The ARC 312 may be excluded from the recesses 504 (and/or from a whole of the electrical pad region 208). The deposition tool 102 may deposit the ARC 312 using a CVD technique, a PVD technique, an ALD technique, or another type of deposition technique.

As shown in FIG. 5C, the recesses 502 may be filled with a dielectric layer 314. Additional dielectric material may be deposited such that an adhesion layer 316 extends along the surface of the substrate 306 in the pixel sensor array 202 and/or in the optical blocking region 206. The adhesion layer 316 may be excluded from the recesses 504 (and/or from a whole of the electrical pad region 208). The deposition tool 102 may deposit the dielectric layer 314 using various CVD techniques and/or ALD techniques, such as PECVD, HDP-CVD, SACVD, and/or PEALD, among other examples.

As shown in FIG. 5D, a recess 506 may be formed in the adhesion layer 316 at a portion of the optical blocking region 206 at (or near) a boundary with the pixel sensor array 202. The recess 506 may be formed as part of forming a grounding node 342. Accordingly, the recess 506 may expose a top surface of the substrate 306. In some implementations, the deposition tool 102 may form a photoresist layer on the adhesion layer 316, the exposure tool 104 may expose the photoresist layer to a radiation source to pattern the photoresist layer, the developer tool 106 may develop and remove portions of the photoresist layer to expose the pattern, and the etch tool 108 may etch portions of adhesion layer 316 to form the recess 506 for the grounding node 342 in the adhesion layer 316. In some implementations, the photoresist removal tool 114 removes the remaining portions of the photoresist layer (e.g., using a chemical stripper and/or another technique) after the etch tool 108 etches the adhesion layer 316.

As shown in FIG. 5E, a metal layer 318 may be formed over and/or on the adhesion layer 316. The metal layer 318 may be formed in the pixel sensor array 202 and/or in the optical blocking region 206. The portion of the metal layer 318 in the optical blocking region 206 may correspond to a light-blocking layer for the sensing region 338. Additionally, the metal layer 318 may fill the recess 506 to form the grounding node 342. The deposition tool 102 and/or the plating tool 112 may deposit the metal layer 318 in a CVD operation, a PVD operation, an ALD operation, an electroplating operation, another deposition operation described above in connection with FIG. 1, and/or another suitable deposition operation. In some implementations, a seed layer is first deposited, and the metal layer 318 is deposited on the seed layer. In some implementations, the planarization tool 110 planarizes the metal layer 318 after the deposition tool 102 and/or the plating tool 112 deposits the metal layer 318.

During a same deposition cycle, as further shown in FIG. 5E, an electrical pad 336 may be formed in the recesses 504. For example, the electrical pad 336 may be formed using a same metal as the metal layer 318. The metal may be formed on sidewalls of the recesses 504, such that portions of the electrical pad 336 land on the metallization layer 328.

As shown in FIG. 5F, openings 508 may be formed through the metal layer 318 in the pixel sensor array 202. The openings 508 may be formed over the photodiodes 308 of the pixel sensors 204 in the pixel sensor array 202. The openings 508 may be formed by removing first portions of the metal layer 318 to form a metal grid 320 above the isolation structure 310. The openings 508 and the metal grid 320 may be formed while the optical blocking region 206 and the electrical pad region 208 are masked (e.g., by a photoresist layer or a hard mask). In some implementations, the deposition tool 102 may form a photoresist layer on the metal layer 318 in the pixel sensor array 202, the exposure tool 104 may expose the photoresist layer to a radiation source to pattern the photoresist layer, the developer tool 106 may develop and remove portions of the photoresist layer to expose the pattern, and the etch tool 108 may etch through portions of the metal layer 318 to form the openings 508. In some implementations, the etch tool 108 etches into a portion of the underlying adhesion layer 316 to ensure that the metal layer 318 is fully etched through. The portions of the underlying adhesion layer 316 that are removed may be referred to as over-etch regions. In some implementations, the photoresist removal tool 114 removes the remaining portions of the photoresist layer (e.g., using a chemical stripper and/or another technique) after the etch tool 108 etches the metal layer 318.

As further shown in FIG. 5F, the metal layer 318 may be patterned into a nanoscale metal grid 340 in the optical blocking region 206. As described in connection with FIG. 3A, the nanoscale metal grid 340 includes a plurality of metal structures, and each metal structure has a width in a range from approximately 100 nm to approximately 200 nm.

In some implementations, the nanoscale metal grid 340 may be formed using double pattern lithography in order to etch nanoscale openings between the metal structures. The nanoscale metal grid 340 may be formed while the pixel sensor array 202 and the electrical pad region 208 are masked (e.g., by a photoresist layer or a hard mask). Alternatively, a same process (e.g., the double pattern lithography) may be used to form the metal grid 320 and the nanoscale metal grid 340. The nanoscale metal grid 340 reduces the likelihood of light being reflected from the optical blocking region 206 and toward the pixel sensor array 202. In this way, the nanoscale metal grid 340 reduces a likelihood of occurrence of flares or hot spots in images and/or videos generated by the example image sensor device 300, which increases image quality. The nanoscale metal grid 340 remains at an electrical neutral via the grounding node 342, even as photons collide with the nanoscale metal grid 340. As a result, current does not leak from the nanoscale metal grid 340 to the pixel sensor array 202, which improves performance of the example image sensor device 300.

As shown in FIG. 5G, respective color filter regions 322 may be formed in the openings 508 for each of the pixel sensors 204 in the pixel sensor array 202. Each color filter region 322 may be formed in between the metal grid 320 to reduce color mixing between adjacent pixel sensors 204. Additionally, or alternatively, the areas between the metal grid 320 may be filled with a passivation layer, and a color filter layer including the color filter regions 322 may be formed on the passivation layer above the metal grid 320. For example, as shown in FIG. 5G, the passivation layer may further be formed in the optical blocking region 206 (and absent from the electrical pad region 208). In some implementations, the deposition tool 102 may deposit the color filter regions 322 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the color filter regions 322 after the deposition tool 102 deposits the color filter regions 322.

As shown in FIG. 5H, a dielectric layer 324 may be formed over the passivation layer in the pixel sensor array 202 and/or the optical blocking region 206; however, the dielectric layer 324 is absent from the electrical pad region 208. The deposition tool 102 may conformally deposit the dielectric layer 324 using a CVD technique, a PVD technique, an ALD technique, or another type of deposition technique.

As shown in FIG. 5I, a micro-lens layer 326 including a plurality of micro-lenses is formed over and/or on the color filter regions 322. The micro-lens layer 326 may include a respective micro-lens for each of the pixel sensors 204 included in the pixel sensor array 202.

As indicated above, FIGS. 5A-5I are provided as an example. Other examples may differ from what is described with regard to FIGS. 5A-5I. For example, the dielectric layer 324 may be omitted from part, or all, of the example image sensor device 300. Additionally, or alternatively, the color filter regions 322 may be omitted and replaced with only the passivation layer described above.

FIGS. 6A-6I are diagrams of an example implementation 600 described herein. Example implementation 600 may be an example process for forming an example image sensor device 350 described herein. The example image sensor device 350 may include a pixel sensor array 202 including a plurality of pixel sensors 204, an optical blocking region 206 including a nanoscale metal grid 340, and an electrical pad region 208, among other examples. In the example implementation 600, the nanoscale metal grid 340 is formed using a recessed pattern in a supporting dielectric layer rather than using double lithography.

As shown in FIG. 6A, the example implementation 600 may include processes described in connection with FIGS. 4A-4E. As further shown in FIG. 6A, a recess 604 may be formed in the adhesion layer 316 at a portion of the optical blocking region 206 at (or near) a boundary with the pixel sensor array 202. The recess 404 may be formed as part of forming a grounding node 342. Accordingly, the recess 404 may expose a top surface of the substrate 306. In some implementations, the deposition tool 102 may form a photoresist layer on the adhesion layer 316, the exposure tool 104 may expose the photoresist layer to a radiation source to pattern the photoresist layer, the developer tool 106 may develop and remove portions of the photoresist layer to expose the pattern, and the etch tool 108 may etch portions of adhesion layer 316 to form the recess 604 for the grounding node 342 in the adhesion layer 316. In some implementations, the photoresist removal tool 114 removes the remaining portions of the photoresist layer (e.g., using a chemical stripper and/or another technique) after the etch tool 108 etches the adhesion layer 316.

In some implementations, as further shown in FIG. 6A, recesses 606 may be formed in the adhesion layer 316 in the electrical pad region 208. The recesses 606 may be formed as part of forming an electrical pad 336. Accordingly, the recesses 606 may expose a top surface of the substrate 306. In some implementations, the pattern exposed by the developer tool 106 may be used to form both the recess 604 and the recesses 606. Alternatively, the adhesion layer 316 may be etched in the electrical pad region 208 during a later etching cycle (e.g., the etching cycle as described in connection with FIG. 6E).

As further shown in FIG. 6A, the adhesion layer 316 may be patterned into a recessed pattern 352 in the optical blocking region 206. As described in connection with FIG. 3B, the adhesion layer 316 may be patterned such that a metal layer 318 in the optical blocking region 206 will follow the recessed pattern 352 during deposition. In some implementations, the recessed pattern 352 may be formed using double pattern lithography in order to etch holes in the adhesion layer 316. The recessed pattern 352 may be formed while the pixel sensor array 202 and the electrical pad region 208 are masked (e.g., by a photoresist layer or a hard mask). Alternatively, a same process (e.g., the double pattern lithography) may be used to form the recessed pattern 352 with the recess 604 and/or the recesses 606. Therefore, the adhesion layer 316 in the pixel sensor array 202 may also conform to the recessed pattern 352.

As shown in FIG. 6B, a metal layer 318 may be formed over and/or on the adhesion layer 316. The metal layer 318 may be formed in the pixel sensor array 202, in the optical blocking region 206, and in the electrical pad region 208, among other examples. The portion of the metal layer 318 in the optical blocking region 206 may correspond to a light-blocking layer for the sensing region 338. Additionally, the metal layer 318 may fill the recess 604 to form the grounding node 342. The deposition tool 102 and/or the plating tool 112 may deposit the metal layer 318 in a CVD operation, a PVD operation, an ALD operation, an electroplating operation, another deposition operation described above in connection with FIG. 1, and/or another suitable deposition operation. In some implementations, a seed layer is first deposited, and the metal layer 318 is deposited on the seed layer. In some implementations, the planarization tool 110 planarizes the metal layer 318 after the deposition tool 102 and/or the plating tool 112 deposits the metal layer 318.

As further shown in FIG. 6B, a deposition rate of the metal layer 318 may be relatively constant such that the metal layer 318 follows the recessed pattern 352 (albeit with reduced roughness because metal flows, unlike dielectric material). The metal layer 318 follows the recessed pattern 352 in the optical blocking region 206. In implementations where the adhesion layer 316 in the pixel sensor array 202 follows the recessed pattern 352, the metal layer 318 may also follow the recessed pattern 352 in the pixel sensor array 202.

As shown in FIG. 6C, openings 608 may be formed through the metal layer 318 in the pixel sensor array 202. The openings 608 may be formed over the photodiodes 308 of the pixel sensors 204 in the pixel sensor array 202. The openings 608 may be formed by removing first portions of the metal layer 318 to form a metal grid 320 above the isolation structure 310. The openings 608 and the metal grid 320 may be formed while the optical blocking region 206 and the electrical pad region 208 are masked (e.g., by a photoresist layer or a hard mask). In some implementations, the deposition tool 102 may form a photoresist layer on the metal layer 318 in the pixel sensor array 202, the exposure tool 104 may expose the photoresist layer to a radiation source to pattern the photoresist layer, the developer tool 106 may develop and remove portions of the photoresist layer to expose the pattern, and the etch tool 108 may etch through portions of the metal layer 318 to form the openings 608. In some implementations, the etch tool 108 etches into a portion of the underlying adhesion layer 316 to ensure that the metal layer 318 is fully etched through. The portions of the underlying adhesion layer 316 that are removed may be referred to as over-etch regions. In some implementations, the photoresist removal tool 114 removes the remaining portions of the photoresist layer (e.g., using a chemical stripper and/or another technique) after the etch tool 108 etches the metal layer 318.

In some implementations, as further shown in FIG. 6C, the recesses 606 may be re-opened in the metal layer 318 in the electrical pad region 208. The recesses 606 may be formed as part of forming the metal grid 320 and the nanoscale metal grid 340 (e.g., using double pattern lithography). Alternatively, the metal layer 318 may be etched in the electrical pad region 208 during a later etching cycle (e.g., the etching cycle as described in connection with FIG. 6E).

As shown in FIG. 6D, respective color filter regions 322 may be formed in the openings 608 for each of the pixel sensors 204 in the pixel sensor array 202. Each color filter region 322 may be formed in between the metal grid 320 to reduce color mixing between adjacent pixel sensors 204. Additionally, or alternatively, the areas between the metal grid 320 may be filled with a passivation layer, and a color filter layer including the color filter regions 322 may be formed on the passivation layer above the metal grid 320. For example, as shown in FIG. 6D, the passivation layer may further be formed in the optical blocking region 206 and/or the electrical pad region 208. In some implementations, the deposition tool 102 may deposit the color filter regions 322 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the color filter regions 322 after the deposition tool 102 deposits the color filter regions 322.

As shown in FIG. 6E, a recess 332 may be formed in the electrical pad region 208. In particular, the recess 332 may be formed through the passivation layer, through the metal layer 318, through the adhesion layer 316, through the ARC 312, and into the substrate 306 to the STI region 330. The STI region 330 may be exposed through the recess 332. The recess 332 may be formed by coating the passivation layer with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching the recess 332 (e.g., using the etch tool 108) based on the pattern in the photoresist.

As shown in FIG. 6F, a dielectric layer 324 may be formed over the passivation layer in the pixel sensor array 202 and/or the optical blocking region 206, as well as over the STI region 330 in the electrical pad region 208. The dielectric layer 324 may also be formed on exposed sidewalls of the recess 332. The deposition tool 102 may conformally deposit the dielectric layer 324 using a CVD technique, a PVD technique, an ALD technique, or another type of deposition technique. Other implementations may omit the dielectric layer 324 from the electrical pad region 208 (e.g., as described in connection with FIG. 5I).

As shown in FIG. 6G, openings 610 may be formed in the recess 332 of the electrical pad region 208. In particular, the openings 610 may be formed through the dielectric layer 324 (if present), through the STI region 330, and through the ILD layer 304, to the metallization layer 328 in the IMD layer 302. The openings 610 may be formed by coating the dielectric layer 324 with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching the openings 610 (e.g., using the etch tool 108) based on the pattern in the photoresist.

As shown in FIG. 6H, an electrical pad 336 may be formed in the openings 610. For example, a semiconductor processing tool (e.g., the deposition tool 102 or the plating tool 112) may form a metal layer (e.g., an aluminum layer, a copper layer, a tungsten layer, a gold layer, a silver layer, a metal alloy layer, or another type of metal layer) on the dielectric layer 334 (if present) and on sidewalls of the openings 610, such that portions of the electrical pad 336 land on the metallization layer 328.

As shown in FIG. 6I, a micro-lens layer 326 including a plurality of micro-lenses is formed over and/or on the color filter regions 322. The micro-lens layer 326 may include a respective micro-lens for each of the pixel sensors 204 included in the pixel sensor array 202.

As indicated above, FIGS. 6A-6I are provided as an example. Other examples may differ from what is described with regard to FIGS. 6A-6I. For example, the dielectric layer 324 may be omitted from part, or all, of the example image sensor device 350. Additionally, or alternatively, the color filter regions 322 may be omitted and replaced with only the passivation layer described above. Additionally, or alternatively, the electrical pad 336 may be formed earlier (e.g., during formation of the metal layer 318, as described in connection with FIG. 5E).

FIGS. 7A-7L are diagrams of an example implementation 700 described herein. Example implementation 700 may be an example process for forming an example image sensor device 360 described herein. The example image sensor device 360 may include a pixel sensor array 202 including a plurality of pixel sensors 204, an optical blocking region 206 including a nanoscale metal grid 340, and an electrical pad region 208, among other examples. In the example implementation 700, the nanoscale metal grid 340 is formed using HA structures in a supporting dielectric layer rather than using double lithography.

As shown in FIG. 7A, the example implementation 700 may include processes described in connection with FIGS. 4A-4C. As further shown in FIG. 7A, the substrate 306 may be patterned into a recessed pattern 362 in the optical blocking region 206. As described in connection with FIG. 3C, the substrate 306 may be patterned such that a adhesion layer 316 and a metal layer 318 in the optical blocking region 206 will follow the recessed pattern 362 during deposition. In some implementations, the recessed pattern 362 may include approximately pyramidal holes. The recessed pattern 362 may be formed while the pixel sensor array 202 and the electrical pad region 208 are masked (e.g., by a photoresist layer or a hard mask). Alternatively, a same process may be used to form the recessed pattern 362 with the recesses 702.

As shown in FIG. 7B, an ARC 312 may be formed above and/or on the substrate 306 as well as in the recesses 702 and the recessed pattern 362. The ARC 312 may be conformally deposited such that the ARC 312 includes a thin film that conforms to the shape and/or profile of the recesses 702 and the recessed pattern 362. The ARC 312 may be included on the surface of the substrate 306 in the pixel sensor array 202, in the optical blocking region 206, and/or in the electrical pad region 208, among other examples. The deposition tool 102 may deposit the ARC 312 using a CVD technique, a PVD technique, an ALD technique, or another type of deposition technique.

As shown in FIG. 7C, the recesses 702 may be filled with the dielectric layer 314 to form the isolation structure 310. Additionally, the recessed pattern 362 may be filled with the dielectric layer 314 to form a plurality of HA structures. The dielectric material used in the recesses 702 may be a same material or a different material as used in the recessed pattern 362.

Additional dielectric material may be deposited such that an adhesion layer 316 extends along the surface of the substrate 306 in the pixel sensor array 202, in the optical blocking region 206, and in the electrical pad region 208, among other examples. The deposition tool 102 may deposit the dielectric layer 314 using various CVD techniques and/or ALD techniques, such as PECVD, HDP-CVD, SACVD, and/or PEALD, among other examples. As further shown in FIG. 7C, the dielectric material used in the recessed pattern 362 may be deposited conformally such that the adhesion layer 316 follows the recessed pattern 362 (albeit with reduced roughness) in the optical blocking region 206.

As shown in FIG. 7D, a recess 704 may be formed in the adhesion layer 316 at a portion of the optical blocking region 206 at (or near) a boundary with the pixel sensor array 202. The recess 704 may be formed as part of forming a grounding node 342. Accordingly, the recess 704 may expose a top surface of the substrate 306. In some implementations, the deposition tool 102 may form a photoresist layer on the adhesion layer 316, the exposure tool 104 may expose the photoresist layer to a radiation source to pattern the photoresist layer, the developer tool 106 may develop and remove portions of the photoresist layer to expose the pattern, and the etch tool 108 may etch portions of adhesion layer 316 to form the recess 704 for the grounding node 342 in the adhesion layer 316. In some implementations, the photoresist removal tool 114 removes the remaining portions of the photoresist layer (e.g., using a chemical stripper and/or another technique) after the etch tool 108 etches the adhesion layer 316.

In some implementations, as further shown in FIG. 7D, recesses 706 may be formed in the adhesion layer 316 in the electrical pad region 208. The recesses 706 may be formed as part of forming an electrical pad 336. Accordingly, the recesses 706 may expose a top surface of the substrate 306. In some implementations, the pattern exposed by the developer tool 106 may be used to form both the recess 704 and the recesses 706. Alternatively, the adhesion layer 316 may be etched in the electrical pad region 208 during a later etching cycle (e.g., the etching cycle as described in connection with FIG. 7H).

As shown in FIG. 7E, a metal layer 318 may be formed over and/or on the adhesion layer 316. The metal layer 318 may be formed in the pixel sensor array 202, in the optical blocking region 206, and in the electrical pad region 208, among other examples. The portion of the metal layer 318 in the optical blocking region 206 may correspond to a light-blocking layer for the sensing region 338. Additionally, the metal layer 318 may fill the recess 704 to form the grounding node 342. The deposition tool 102 and/or the plating tool 112 may deposit the metal layer 318 in a CVD operation, a PVD operation, an ALD operation, an electroplating operation, another deposition operation described above in connection with FIG. 1, and/or another suitable deposition operation. In some implementations, a seed layer is first deposited, and the metal layer 318 is deposited on the seed layer. In some implementations, the planarization tool 110 planarizes the metal layer 318 after the deposition tool 102 and/or the plating tool 112 deposits the metal layer 318.

As further shown in FIG. 7E, a deposition rate of the metal layer 318 may be relatively constant such that the metal layer 318 follows the recessed pattern 362 (albeit with reduced roughness because metal flows). The metal layer 318 conforms to the recessed pattern 362 in the optical blocking region 206.

As shown in FIG. 7F, openings 708 may be formed through the metal layer 318 in the pixel sensor array 202. The openings 708 may be formed over the photodiodes 308 of the pixel sensors 204 in the pixel sensor array 202. The openings 708 may be formed by removing first portions of the metal layer 318 to form a metal grid 320 above the isolation structure 310. The openings 608 and the metal grid 320 may be formed while the optical blocking region 206 and the electrical pad region 208 are masked (e.g., by a photoresist layer or a hard mask). In some implementations, the deposition tool 102 may form a photoresist layer on the metal layer 318 in the pixel sensor array 202, the exposure tool 104 may expose the photoresist layer to a radiation source to pattern the photoresist layer, the developer tool 106 may develop and remove portions of the photoresist layer to expose the pattern, and the etch tool 108 may etch through portions of the metal layer 318 to form the openings 708. In some implementations, the etch tool 108 etches into a portion of the underlying adhesion layer 316 to ensure that the metal layer 318 is fully etched through. The portions of the underlying adhesion layer 316 that are removed may be referred to as over-etch regions. In some implementations, the photoresist removal tool 114 removes the remaining portions of the photoresist layer (e.g., using a chemical stripper and/or another technique) after the etch tool 108 etches the metal layer 318.

In some implementations, as further shown in FIG. 7F, the recesses 706 may be re-opened in the metal layer 318 in the electrical pad region 208. The recesses 706 may be formed as part of forming the metal grid 320 and the nanoscale metal grid 340 (e.g., using double pattern lithography). Alternatively, the metal layer 318 may be etched in the electrical pad region 208 during a later etching cycle (e.g., the etching cycle as described in connection with FIG. 7H).

As shown in FIG. 7G, respective color filter regions 322 may be formed in the openings 708 for each of the pixel sensors 204 in the pixel sensor array 202. Each color filter region 322 may be formed in between the metal grid 320 to reduce color mixing between adjacent pixel sensors 204. Additionally, or alternatively, the areas between the metal grid 320 may be filled with a passivation layer, and a color filter layer including the color filter regions 322 may be formed on the passivation layer above the metal grid 320. For example, as shown in FIG. 7G, the passivation layer may further be formed in the optical blocking region 206 and/or the electrical pad region 208. In some implementations, the deposition tool 102 may deposit the color filter regions 322 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the color filter regions 322 after the deposition tool 102 deposits the color filter regions 322.

As shown in FIG. 7H, a recess 332 may be formed in the electrical pad region 208. In particular, the recess 332 may be formed through the passivation layer, through the metal layer 318, through the adhesion layer 316, through the ARC 312, and into the substrate 306 to the STI region 330. The STI region 330 may be exposed through the recess 332. The recess 332 may be formed by coating the passivation layer with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching the recess 332 (e.g., using the etch tool 108) based on the pattern in the photoresist.

As shown in FIG. 7I, a dielectric layer 324 may be formed over the passivation layer in the pixel sensor array 202 and/or the optical blocking region 206, as well as over the STI region 330 in the electrical pad region 208. The dielectric layer 324 may also be formed on exposed sidewalls of the recess 332. The deposition tool 102 may conformally deposit the dielectric layer 324 using a CVD technique, a PVD technique, an ALD technique, or another type of deposition technique. Other implementations may omit the dielectric layer 324 from the electrical pad region 208 (e.g., as described in connection with FIG. 5I).

As shown in FIG. 7J, openings 710 may be formed in the recess 332 of the electrical pad region 208. In particular, the openings 710 may be formed through the dielectric layer 324 (if present), through the STI region 330, and through the ILD layer 304, to the metallization layer 328 in the IMD layer 302. The openings 710 may be formed by coating the dielectric layer 324 with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching the openings 710 (e.g., using the etch tool 108) based on the pattern in the photoresist.

As shown in FIG. 7K, an electrical pad 336 may be formed in the openings 710. For example, a semiconductor processing tool (e.g., the deposition tool 102 or the plating tool 112) may form a metal layer (e.g., an aluminum layer, a copper layer, a tungsten layer, a gold layer, a silver layer, a metal alloy layer, or another type of metal layer) on the dielectric layer 334 (if present) and on sidewalls of the openings 710, such that portions of the electrical pad 336 land on the metallization layer 328.

As shown in FIG. 7L, a micro-lens layer 326 including a plurality of micro-lenses is formed over and/or on the color filter regions 322. The micro-lens layer 326 may include a respective micro-lens for each of the pixel sensors 204 included in the pixel sensor array 202.

As indicated above, FIGS. 7A-7L are provided as an example. Other examples may differ from what is described with regard to FIGS. 7A-7L. For example, the dielectric layer 324 may be omitted from part, or all, of the example image sensor device 360. Additionally, or alternatively, the color filter regions 322 may be omitted and replaced with only the passivation layer described above. Additionally, or alternatively, the electrical pad 336 may be formed earlier (e.g., during formation of the metal layer 318, as described in connection with FIG. 5E). FIGS. 8A-8L are diagrams of an example implementation 800 described herein.

Example implementation 800 may be an example process for forming an example image sensor device 370 described herein. The example image sensor device 370 may include a pixel sensor array 202 including a plurality of pixel sensors 204, an optical blocking region 206 including a nanoscale metal grid 340, and an electrical pad region 208, among other examples. In the example implementation 800, the nanoscale metal grid 340 is formed using shallow isolation structures in a supporting dielectric layer rather than using double lithography.

As shown in FIG. 8A, the example implementation 800 may include processes described in connection with FIGS. 4A-4C. As further shown in FIG. 8A, the substrate 306 may be patterned into a recessed pattern 372 in the optical blocking region 206. As described in connection with FIG. 3D, the substrate 306 may be patterned such that a adhesion layer 316 and a metal layer 318 in the optical blocking region 206 will follow the recessed pattern 372 during deposition. In some implementations, the recessed pattern 372 may include shallow trenches (e.g., for shallow DTI structures). The recessed pattern 372 may be formed while the pixel sensor array 202 and the electrical pad region 208 are masked (e.g., by a photoresist layer or a hard mask). Alternatively, a same process may be used to form the recessed pattern 372 with the recesses 802.

As shown in FIG. 8B, an ARC 312 may be formed above and/or on the substrate 306 as well as in the recesses 802 and the recessed pattern 372. The ARC 312 may be conformally deposited such that the ARC 312 includes a thin film that conforms to the shape and/or profile of the recesses 802 and the recessed pattern 372. The ARC 312 may be included on the surface of the substrate 306 in the pixel sensor array 202, in the optical blocking region 206, and/or in the electrical pad region 208, among other examples. The deposition tool 102 may deposit the ARC 312 using a CVD technique, a PVD technique, an ALD technique, or another type of deposition technique.

As shown in FIG. 8C, the recesses 802 may be filled with the dielectric layer 314 to form the isolation structure 310. Additionally, the recessed pattern 372 may be filled with the dielectric layer 314 to form a plurality of shallow isolation structures. The dielectric material used in the recesses 802 may be a same material or a different material as used in the recessed pattern 372.

Additional dielectric material may be deposited such that an adhesion layer 316 extends along the surface of the substrate 306 in the pixel sensor array 202, in the optical blocking region 206, and in the electrical pad region 208, among other examples. The deposition tool 102 may deposit the dielectric layer 314 using various CVD techniques and/or ALD techniques, such as PECVD, HDP-CVD, SACVD, and/or PEALD, among other examples. As further shown in FIG. 8C, the dielectric material used in the recessed pattern 372 may be deposited conformally such that the adhesion layer 316 follows the recessed pattern 372 (albeit with reduced roughness) in the optical blocking region 206.

As shown in FIG. 8D, a recess 804 may be formed in the adhesion layer 316 at a portion of the optical blocking region 206 at (or near) a boundary with the pixel sensor array 202. The recess 804 may be formed as part of forming a grounding node 342. Accordingly, the recess 804 may expose a top surface of the substrate 306. In some implementations, the deposition tool 102 may form a photoresist layer on the adhesion layer 316, the exposure tool 104 may expose the photoresist layer to a radiation source to pattern the photoresist layer, the developer tool 106 may develop and remove portions of the photoresist layer to expose the pattern, and the etch tool 108 may etch portions of adhesion layer 316 to form the recess 804 for the grounding node 342 in the adhesion layer 316. In some implementations, the photoresist removal tool 114 removes the remaining portions of the photoresist layer (e.g., using a chemical stripper and/or another technique) after the etch tool 108 etches the adhesion layer 316.

In some implementations, as further shown in FIG. 8D, recesses 806 may be formed in the adhesion layer 316 in the electrical pad region 208. The recesses 806 may be formed as part of forming an electrical pad 336. Accordingly, the recesses 806 may expose a top surface of the substrate 306. In some implementations, the pattern exposed by the developer tool 106 may be used to form both the recess 804 and the recesses 806. Alternatively, the adhesion layer 316 may be etched in the electrical pad region 208 during a later etching cycle (e.g., the etching cycle as described in connection with FIG. 8H).

As shown in FIG. 8E, a metal layer 318 may be formed over and/or on the adhesion layer 316. The metal layer 318 may be formed in the pixel sensor array 202, in the optical blocking region 206, and in the electrical pad region 208, among other examples. The portion of the metal layer 318 in the optical blocking region 206 may correspond to a light-blocking layer for the sensing region 338. Additionally, the metal layer 318 may fill the recess 804 to form the grounding node 342. The deposition tool 102 and/or the plating tool 112 may deposit the metal layer 318 in a CVD operation, a PVD operation, an ALD operation, an electroplating operation, another deposition operation described above in connection with FIG. 1, and/or another suitable deposition operation. In some implementations, a seed layer is first deposited, and the metal layer 318 is deposited on the seed layer. In some implementations, the planarization tool 110 planarizes the metal layer 318 after the deposition tool 102 and/or the plating tool 112 deposits the metal layer 318.

As further shown in FIG. 8E, a deposition rate of the metal layer 318 may be relatively constant such that the metal layer 318 follows the recessed pattern 372 (albeit with reduced roughness because metal flows). The metal layer 318 conforms to the recessed pattern 372 in the optical blocking region 206.

As shown in FIG. 8F, openings 808 may be formed through the metal layer 318 in the pixel sensor array 202. The openings 808 may be formed over the photodiodes 308 of the pixel sensors 204 in the pixel sensor array 202. The openings 808 may be formed by removing first portions of the metal layer 318 to form a metal grid 320 above the isolation structure 310. The openings 808 and the metal grid 320 may be formed while the optical blocking region 206 and the electrical pad region 208 are masked (e.g., by a photoresist layer or a hard mask). In some implementations, the deposition tool 102 may form a photoresist layer on the metal layer 318 in the pixel sensor array 202, the exposure tool 104 may expose the photoresist layer to a radiation source to pattern the photoresist layer, the developer tool 106 may develop and remove portions of the photoresist layer to expose the pattern, and the etch tool 108 may etch through portions of the metal layer 318 to form the openings 808. In some implementations, the etch tool 108 etches into a portion of the underlying adhesion layer 316 to ensure that the metal layer 318 is fully etched through. The portions of the underlying adhesion layer 316 that are removed may be referred to as over-etch regions. In some implementations, the photoresist removal tool 114 removes the remaining portions of the photoresist layer (e.g., using a chemical stripper and/or another technique) after the etch tool 108 etches the metal layer 318.

In some implementations, as further shown in FIG. 8F, the recesses 806 may be re-opened in the metal layer 318 in the electrical pad region 208. The recesses 806 may be formed as part of forming the metal grid 320 and the nanoscale metal grid 340 (e.g., using double pattern lithography). Alternatively, the metal layer 318 may be etched in the electrical pad region 208 during a later etching cycle (e.g., the etching cycle as described in connection with FIG. 8H).

As shown in FIG. 8G, respective color filter regions 322 may be formed in the openings 808 for each of the pixel sensors 204 in the pixel sensor array 202. Each color filter region 322 may be formed in between the metal grid 320 to reduce color mixing between adjacent pixel sensors 204. Additionally, or alternatively, the areas between the metal grid 320 may be filled with a passivation layer, and a color filter layer including the color filter regions 322 may be formed on the passivation layer above the metal grid 320. For example, as shown in FIG. 8G, the passivation layer may further be formed in the optical blocking region 206 and/or the electrical pad region 208. In some implementations, the deposition tool 102 may deposit the color filter regions 322 in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the color filter regions 322 after the deposition tool 102 deposits the color filter regions 322.

As shown in FIG. 8H, a recess 332 may be formed in the electrical pad region 208. In particular, the recess 332 may be formed through the passivation layer, through the metal layer 318, through the adhesion layer 316, through the ARC 312, and into the substrate 306 to the STI region 330. The STI region 330 may be exposed through the recess 332. The recess 332 may be formed by coating the passivation layer with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching the recess 332 (e.g., using the etch tool 108) based on the pattern in the photoresist.

As shown in FIG. 8I, a dielectric layer 324 may be formed over the passivation layer in the pixel sensor array 202 and/or the optical blocking region 206, as well as over the STI region 330 in the electrical pad region 208. The dielectric layer 324 may also be formed on exposed sidewalls of the recess 332. The deposition tool 102 may conformally deposit the dielectric layer 324 using a CVD technique, a PVD technique, an ALD technique, or another type of deposition technique. Other implementations may omit the dielectric layer 324 from the electrical pad region 208 (e.g., as described in connection with FIG. 5I).

As shown in FIG. 8J, openings 810 may be formed in the recess 332 of the electrical pad region 208. In particular, the openings 810 may be formed through the dielectric layer 324 (if present), through the STI region 330, and through the ILD layer 304, to the metallization layer 328 in the IMD layer 302. The openings 810 may be formed by coating the dielectric layer 324 with a photoresist (e.g., using the deposition tool 102), forming a pattern in the photoresist by exposing the photoresist to a radiation source (e.g., using the exposure tool 104), removing either the exposed portions or the non-exposed portions of the photoresist (e.g., using developer tool 106), and etching the openings 810 (e.g., using the etch tool 108) based on the pattern in the photoresist.

As shown in FIG. 8K, an electrical pad 336 may be formed in the openings 810. For example, a semiconductor processing tool (e.g., the deposition tool 102 or the plating tool 112) may form a metal layer (e.g., an aluminum layer, a copper layer, a tungsten layer, a gold layer, a silver layer, a metal alloy layer, or another type of metal layer) on the dielectric layer 334 (if present) and on sidewalls of the openings 810, such that portions of the electrical pad 336 land on the metallization layer 328.

As shown in FIG. 8L, a micro-lens layer 326 including a plurality of micro-lenses is formed over and/or on the color filter regions 322. The micro-lens layer 326 may include a respective micro-lens for each of the pixel sensors 204 included in the pixel sensor array 202.

As indicated above, FIGS. 8A-8L are provided as an example. Other examples may differ from what is described with regard to FIGS. 8A-8L. For example, the dielectric layer 324 may be omitted from part, or all, of the example image sensor device 370. Additionally, or alternatively, the color filter regions 322 may be omitted and replaced with only the passivation layer described above. Additionally, or alternatively, the electrical pad 336 may be formed earlier (e.g., during formation of the metal layer 318, as described in connection with FIG. 5E).

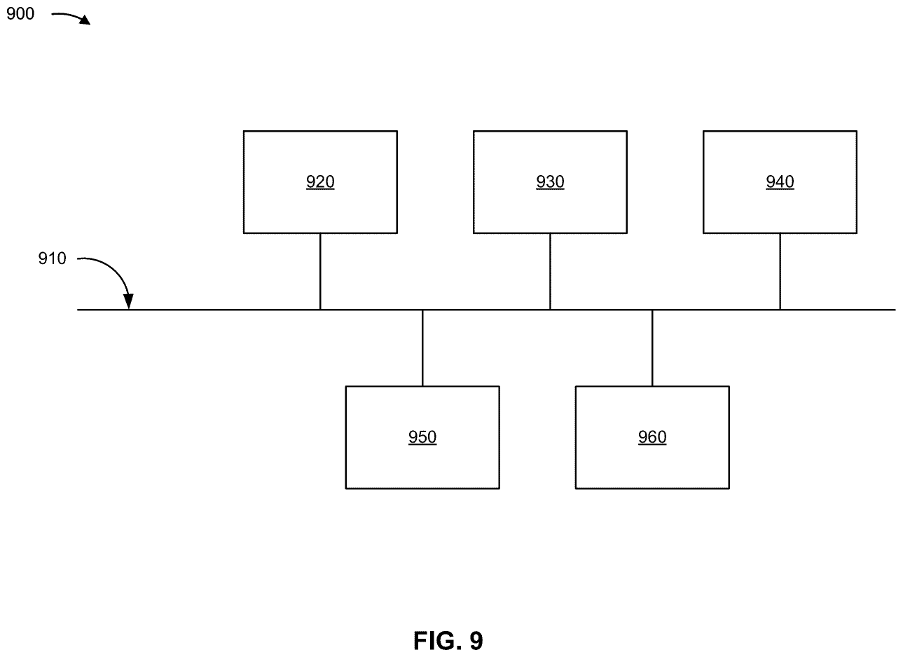

FIG. 9 is a diagram of example components of a device 900 described herein. In some implementations, one or more of the semiconductor processing tools 102-116 and/or the wafer/die transport tool 118 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

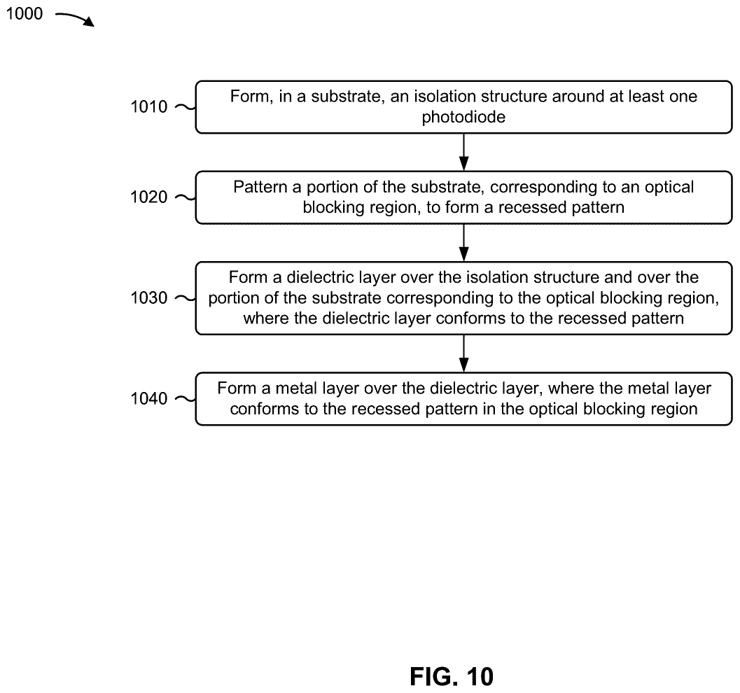

FIG. 10 is a flowchart of an example process 1000 associated with forming a semiconductor device described herein. In some implementations, one or more process blocks of FIG. 10 are performed by one or more semiconductor processing tools (e.g., one or more of the semiconductor processing tools 102-116). Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include forming, in a substrate, an isolation structure around at least one photodiode (block 1010). For example, one or more of the semiconductor processing tools 102-116 may form, in a substrate 306, an isolation structure 310 around at least one photodiode 308, as described herein.

As further shown in FIG. 10, process 1000 may include patterning a portion of the substrate, corresponding to an optical blocking region, to form a recessed pattern (block 1020). For example, one or more of the semiconductor processing tools 102-116 may pattern a portion of the substrate 306, corresponding to an optical blocking region 206, to form a recessed pattern 362 or 372, as described herein.

As further shown in FIG. 10, process 1000 may include forming a dielectric layer over the isolation structure and over the portion of the substrate corresponding to the optical blocking region, where the dielectric layer conforms to the recessed pattern (block 1030). For example, one or more of the semiconductor processing tools 102-116 may form a adhesion layer 316 over the isolation structure 310 and over the portion of the substrate 306 corresponding to the optical blocking region 206, such that the adhesion layer 316 conforms to the recessed pattern 362 or 372, as described herein.

As further shown in FIG. 10, process 1000 may include forming a metal layer over the dielectric layer, where the metal layer conforms to the recessed pattern in the optical blocking region (block 1040). For example, one or more of the semiconductor processing tools 102-116 may form a metal layer 318 over the adhesion layer 316, such that the metal layer 318 conforms to the recessed pattern 362 or 372 in the optical blocking region 206, as described herein.

Process 1000 may include additional implementations, such as any single implementation or any combination of implementations described below and/or in connection with one or more other processes described elsewhere herein.

In a first implementation, patterning the portion of the substrate 306 includes forming HA regions, in the substrate 306, that are approximately pyramidal.

In a second implementation, alone or in combination with the first implementation, each of the HA regions is associated with an angle in a range from approximately 54° to approximately 55°.

In a third implementation, alone or in combination with one or more of the first and second implementations, patterning the portion of the substrate 306 includes forming shallow isolation structures 374 in the substrate 306.

In a fourth implementation, alone or in combination with one or more of the first through third implementations, each of the shallow isolation structures has a width in a range from approximately 100 nm to approximately 400 nm.

In a fifth implementation, alone or in combination with one or more of the first through fourth implementations, forming the metal layer 318 includes forming the metal layer 318 over the adhesion layer 316 in the optical blocking region 206 and over the isolation structure 310 to form a metal grid 320.

In a sixth implementation, alone or in combination with one or more of the first through fifth implementations, forming the metal layer 318 further includes forming an electrical pad 336 over an electrical pad region 208.

In a seventh implementation, alone or in combination with one or more of the first through sixth implementations, forming the metal layer 318 further includes forming a grounding node 342, adjacent to the at least one photodiode 308, that is connected to the substrate 306.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, an optical blocking region formed with patterned metal reduces light reflection toward pixel sensors in a pixel sensor array. The optical blocking region may be formed of a metal nanoscale grid in order to reflect more light away from the pixel sensors. The optical blocking region may include a dielectric layer, supporting the patterned metal, with HA structures or shallow DTI structures in order to increase absorption and thus reduce light reflection toward the pixel sensors.

As described in greater detail above, some implementations described herein provide a semiconductor device. The semiconductor device includes at least one pixel sensor. The semiconductor device includes an optical blocking region adjacent to the at least one pixel sensor. The optical blocking region includes a substrate, a dielectric layer over the substrate, and a metal layer, over the dielectric layer, including a nanoscale grid and configured to reflect light away from the at least one pixel sensor.

As described in greater detail above, some implementations described herein provide a method. The method includes forming, in a substrate, an isolation structure around at least one photodiode. The method includes patterning a portion of the substrate, corresponding to an optical blocking region, to form a recessed pattern. The method includes forming a dielectric layer over the isolation structure and over the portion of the substrate corresponding to the optical blocking region, where the dielectric layer conforms to the recessed pattern. The method includes forming a metal layer over the dielectric layer, where the metal layer conforms to the recessed pattern in the optical blocking region.

As described in greater detail above, some implementations described herein provide a semiconductor device. The semiconductor device includes at least one pixel sensor. The semiconductor device includes an optical blocking region adjacent to the at least one pixel sensor. The optical blocking region includes a substrate, a dielectric layer over the substrate and including a recessed pattern, and a metal layer, over the dielectric layer, conforming to the recessed pattern and configured to reflect light away from the at least one pixel sensor.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
at least one pixel sensor; and
an optical blocking region, adjacent to the at least one pixel sensor, comprising:
a substrate;
a dielectric layer over the substrate; and
a metal layer, over the dielectric layer, including a nanoscale grid and configured to reflect light away from the at least one pixel sensor.

2. The semiconductor device of claim 1, wherein the nanoscale grid comprises a plurality of metal structures, and each metal structure has a width in a range from approximately 100 nanometers (nm) to approximately 200 nm.

3. The semiconductor device of claim 1, further comprising:
a portion of the metal layer, between the nanoscale grid and the at least one pixel sensor, that is connected to the substrate for grounding.

4. The semiconductor device of claim 1, further comprising:
an isolation structure around at least one photodiode of the at least one pixel sensor; and
a metal grid over the isolation structure.

5. A method, comprising:
forming, in a substrate, an isolation structure around at least one photodiode;
patterning a portion of the substrate, corresponding to an optical blocking region, to form a recessed pattern;
forming a dielectric layer over the isolation structure and over the portion of the substrate corresponding to the optical blocking region, wherein the dielectric layer conforms to the recessed pattern; and
forming a metal layer over the dielectric layer, wherein the metal layer conforms to the recessed pattern in the optical blocking region.

6. The method of claim 5, wherein patterning the portion of the substrate comprises:
forming high absorption (HA) regions, in the substrate, that are approximately pyramidal.

7. The method of claim 6, wherein each of the HA regions is associated with an angle in a range from approximately 54 degrees to approximately 55 degrees.

8. The method of claim 5, wherein patterning the portion of the substrate comprises:
forming shallow isolation structures in the substrate.

9. The method of claim 8, wherein each of the shallow isolation structures has a width in a range from approximately 100 nanometers (nm) to approximately 400 nm.

10. The method of claim 5, wherein forming the metal layer comprises:
forming the metal layer over the dielectric layer in the optical blocking region and over the isolation structure to form a metal grid.

11. The method of claim 5, wherein forming the metal layer further comprises:
forming an electrical pad over an electrical pad region.

12. The method of claim 5, wherein forming the metal layer further comprises:
forming a grounding node, adjacent to the at least one photodiode, that is connected to the substrate.

13. A semiconductor device, comprising:
at least one pixel sensor; and
an optical blocking region, adjacent to the at least one pixel sensor, comprising:
a substrate;
a dielectric layer over the substrate and including a recessed pattern; and
a metal layer, over the dielectric layer, conforming to the recessed pattern and configured to reflect light away from the at least one pixel sensor,
wherein the metal layer additionally forms a metal grid over an isolation structure that at least partially surrounds at least one photodiode of the at least one pixel sensor.

14. The semiconductor device of claim 13, wherein the metal grid follows the recessed pattern.

15. The semiconductor device of claim 13, wherein the substrate includes the recessed pattern under the dielectric layer.

16. The semiconductor device of claim 15, wherein the recessed pattern in the substrate includes a plurality of high absorption (HA) regions, that are approximately pyramidal.

17. The semiconductor device of claim 16, wherein each of the HA regions is associated with an angle in a range from approximately 54 degrees to approximately 55 degrees.

18. The semiconductor device of claim 15, wherein the recessed pattern in the substrate includes a plurality of shallow isolation structures.

19. The semiconductor device of claim 18, wherein each of the shallow isolation structures has a depth in a range from approximately 0.5 micrometers (μm) to approximately 6.0 μm.

20. The semiconductor device of claim 13, further comprising:
a portion of the metal layer, adjacent to the at least one pixel sensor, that is connected to the substrate for grounding.
